(19) United States
(12) Patent Application Publication
(10) Pub. No.: US 2005/0241690 A1
(43) Pub. Date: Nov. 3, 2005

(54) Thermoelectric Module

(75) Inventors: Kenichi Tajima, Kokubu-shi (JP); Koichi Tanaka, Kokubu-shi (JP)

Correspondence Address: HOGAN & HARTSON L.L.P., 500 S. GRAND AVENUE, SUITE 1900, LOS ANGELES, CA, 90071-2611, US

(73) Assignee: KYOCERA CORPORATION

(21) Appl. No.: 11/150,707

(22) Filed: Jun. 9, 2005

Related U.S. Application Data
(63) Continuation-in-part of application No. 10/977,114, filed on Oct. 29, 2004.

(30) Foreign Application Priority Data
Oct. 29, 2003 (JP) P 2003-369113
Nov. 26, 2003 (JP) P 2003-395650
Jan. 28, 2004 (JP) P 2004-019874

(51) Int. Cl. H01L 35/28; H01L 37/00; H01L 35/34

(52) U.S. Cl. 136/212; 136/211

(57) ABSTRACT

A thermoelectric module 11 includes support substrates 1a and 1b, the same numbers of N-type thermoelectric elements 2a and P-type thermoelectric elements 2b disposed on the support substrates 1a and 1b, wiring conductors 3a and 3b that electrically connect between the thermoelectric elements in series and an external connection terminal 4 electrically connected to the wiring conductor 3a. The N-type thermoelectric elements 2a and the P-type thermoelectric elements 2b have different values of resistivity.

### BACKGROUND OF THE INVENTION

1. Field of the Invention

The present invention relates to a thermoelectric module that is preferably used in applications of temperature control, keeping coolness and power generation.

2. Description of the Related Art

A thermoelectric element is based on the Peltier effect in that a PN junction device comprising a P-type semiconductor and an N-type semiconductor, with current flowing therethrough, generates heat at one end and absorbs heat at the other end. A thermoelectric module that embodies the Peltier effect in a module is capable of precise temperature control, and is small in size and simple in construction. As such, the thermoelectric module has the potential for practical use in wide applications such as refrigeration apparatus that does not use flon, photo detector device, electronic cooling device for semiconductor manufacturing apparatus and temperature control for laser diode. The thermoelectric element also shows such a reverse action as, when exposed to different temperatures at both ends thereof, a current flows therethrough which may be utilized in power generation by recovering waste heat.

The thermoelectric module is constructed as follows. Two support substrates each have wiring conductor formed thereon. A plurality of thermoelectric elements consisting of P-type thermoelectric elements and N-type thermoelectric elements are interposed between the two support substrates and are bonded by soldering. The same numbers of P-type thermoelectric elements and N-type thermoelectric elements make pairs, and the plurality of pairs are electrically connected in series by means of a wiring conductor in order. Ends of the wiring conductor are further connected with external connection terminals. The external connection terminals are connected with leads by soldering so as to receive power supplied from the outside. Construction of other portions will be described below in more detail.

First, the thermoelectric elements will be described. The thermoelectric module used for cooling purpose at temperatures near the room temperature has such a construction as the same numbers of P-type thermoelectric elements and N-type thermoelectric elements are combined in pairs and are electrically connected in series. The thermoelectric elements are generally made of crystals having the form of A₂B₃ (A represents Bi and/or Sb, and B represents Te and/or Se), for their high cooling performance. Among these, a solid solution of Bi₂Te₃ (bismuth telluride) and Sb₂Te₃ (antimony telluride) used as the P-type thermoelectric element and a solid solution of Bi₂Te₃ and Bi₂Se₃ (bismuth selenide) used as the N-type thermoelectric element show particularly high performance.

Thermoelectric characteristic of these thermoelectric crystals is represented by performance index Z. Performance index Z is defined by Z=S²/ρk, where Z is Seebeck coefficient, ρ is resistivity and k is heat conductivity. The performance index shows the performance and efficiency of a thermoelectric crystal that is used as a thermoelectric element. A thermoelectric module having higher cooling performance and efficiency is obtained by using an N-type thermoelectric element and a P-type thermoelectric element that have higher performance index.

It has been proposed to use a melt-formed material made by a unidirectional solidification method based on known single crystal manufacturing processes such as Bridgman method, pulling (CZ) method and zone melting method for the A₂B₃ crystal (“Thermoelectric Semiconductor and its Applications”, published by THE NIKKAN KOGYO SHIMBUN, LTD., p 149). This enables it to obtain a thermoelectric crystal of high performance index Z that is made from an ingot having uniform crystal orientation or a crystalline material having substantially single crystal property.

The melt-formed material has a problem that it is easily chipped. Therefore, in order to improve the yield of manufacturing the thermoelectric module, it has been proposed to crush an alloy made by melting a mixture of powders of Bi, Sb, Te, Se, etc. and freezing the melt, and sintering the crushed alloy powder while compressing it by a hot press or the like (Japanese Examined Patent Publication (Kokoku) No. 8-32588, Japanese Unexamined Patent Publication (Kokai) No. 1-106478).

The thermoelectric module can be made by combining a plurality of thermoelectric elements that are made from such a sintered material or melt-formed material as described above. In order to improve the performance index and the yield of production or improve the reliability of the thermoelectric module, it has been proposed to make the thermoelectric module by combining the melt-formed material and the sintered material (Japanese Unexamined Patent Publication (Kokai) No. 8-148725 and Japanese Unexamined Patent Publication (Kokai) No. 11-26818).

Furthermore, it has been reported that performance of the thermoelectric module can be improved further by using a monocrystal material for the N-type thermoelectric element and a sintered material for the P-type thermoelectric element and controlling both thermoelectric elements to have substantially the same values of resistivity (U.S. Pat. No. 5,448,109B1).

Now a method of connecting the thermoelectric elements and the wiring conductor will be described. Copper is used for the wiring conductor. The thermoelectric element has electrodes formed on a connection surface thereof by Ni plating or the like. The Ni-plated electrode is formed for the purpose of making the soldering connection between the wiring conductor and the thermoelectric element stronger, improving the wettability of the thermoelectric element with solder and preventing the solder component from diffusing into the thermoelectric element. It has been proposed to form the Ni plating by thermal spraying in order to improve the bonding strength of the Ni plating (Japanese Unexamined Utility Model Publication (Kokai) No. 6-21268). Surface of the Ni electrode is further coated with an Au layer or the like, in order to further improve its wettability with solder.

It has been proposed to make an intermediate portion of the wiring conductor narrower to prevent the thermoelectric elements from being displaced by the surface tension of the molten solder when connecting the thermoelectric element and the wiring conductor with solder (Japanese Patent Publication No. 2544221).

It has also been proposed to form a recess in the wiring conductor to prevent an excess of solder from contacting the side face of the thermoelectric element (Japanese Unexamined Patent Publication (Kokai) No. 10-303470).

Further it has been proposed to form a groove in the wiring conductor in order to purge and reduce voids (bubbles) formed in the solder (Japanese Unexamined Patent Publication (Kokai) No. 9-055541).

Now connection of the thermoelectric module with the outside will be described. Ends of the wiring conductor in the thermoelectric module are connected with external connection terminals. Lead wires are connected to the external connection terminals by soldering, so as to supply power from the outside. For the connection of the leads wires, it has been proposed to use laser beam so as to neat and bond, in order to eliminate short-circuiting and improve the work efficiency (Japanese Patent Publication No. 2583149). Specifically, the wiring conductor electrically connects the thermoelectric elements placed on a support substrate, and external connection electrodes are formed at the ends of the wiring conductors. The leads are connected to the external connection electrodes with solder by irradiating it with YAG laser. However, in addition to special laser bonding technique required for connecting the lead wires, it is necessary to manually connect the lead wires to a package because the connection terminals are contained in the thermoelectric module. This resulted in low yield of production in spite of the substantial labor requirement.

Thus such a thermoelectric module has been proposed having external connection electrode that allows wire bonding from the outside to the ends of the wiring conductor provided in the thermoelectric module (Japanese Patent Publication No. 3082170). This makes it possible to connect the external connection electrodes of the thermoelectric module to the terminals in a laser package with a wire, after mounting the thermoelectric module at the bottom of a package for a semiconductor laser. However, the method disclosed in Japanese Patent Publication No. 3082170 has such a problem that, for example, since the thermoelectric module located near the bottom in the semiconductor laser package and the terminals provided near the top are connected with thin and long wire, the connection involves a high electrical resistance that results in larger power consumption due to heat loss.

It has also been proposed to reduce the length of wire by providing a thin and long extension electrode on an electrode pad. However, it is required to make the extension electrode thin and long, in order to secure sufficient height by means of the extension electrode. When the extension electrode is made thin and long, strength of the extension electrode becomes insufficient leading to such a trouble as the extension electrode is broken or bent during wire bonding, or the extension electrode and the external connection electrode come off at the joint. When the extension electrode is thin and long, in particular, it is difficult to run the electrode straight in the vertical direction, thus frequently resulting in low yield of production in wire bonding process.

It has also been proposed to provide a planar electrode on an upper support substrate of the thermoelectric module, and make connection by means of the electrode terminals provided on the package of a semiconductor laser or the like and wire (for example, Japanese Unexamined Patent Publication (Kokai) No. 11-54806). However, the method disclosed in Japanese Unexamined Patent Publication (Kokai) No. 11-54806 has such a problem that, since wire bonding is applied directly to the support substrate, the brittle thermoelectric elements tend to break due to the shock and the support substrate is subject to warping that may cause cracks between the element and the wiring conductor.

### SUMMARY OF THE INVENTION

There are increasing demands for higher performance of thermoelectric module, and required characteristics have been diversifying. For the application to refrigerator, for example, emphasis is placed on the capacity to absorb heat, namely the heat absorbing characteristic, rather than the temperature difference between the top and bottom surfaces when power is supplied to the thermoelectric module. For the application to the temperature control of a laser diode or the like, a larger temperature difference is required rather than the heat absorbing characteristic in order to maintain the temperature constant.

However, performance of the conventional thermoelectric module has been limited in order to meet these requirements. Since the heat absorbing capacity and the maximum temperature difference both increase with the performance index of the thermoelectric crystal, a module having either only the heat absorbing capacity or only the maximum temperature difference greatly improved cannot be obtained simply by improving the performance of the thermoelectric crystal.

The thermoelectric module is also required to have high reliability. But the conventional thermoelectric module sometimes fails to pass reliability tests for shock, energization cycles, high-temperature operation, etc. Failure to pass the reliability tests occurs from various causes such as deterioration of the thermoelectric elements, deterioration of joint between the thermoelectric elements and the wiring conductor and deterioration of joint between the thermoelectric module and the outside.

Connection of the thermoelectric module and the outside has been made either by connecting lead wires by soldering or by wire bonding, but both methods have problem in reliability. In case the lead wire is soldered onto the thermoelectric module, bonding strength of the lead wire varies and the wire sometimes easily comes off. In case the electrical connection of the thermoelectric module is made by wire bonding, there has been such problems that the wire has high resistance and the thermoelectric element is broken by the shock caused by wire bonding.

An object of the present invention is to solve at least one of the problems of the thermoelectric module described above.

More particularly, a first object of the present invention is to provide a thermoelectric module that is specialized to operate with either high heat absorbing capacity or large temperature difference.

Second object of the present invention is to provide a thermoelectric module of higher reliability.

One embodiment of the thermoelectric module according to the present invention is featured in a combination of the N-type thermoelectric element and the P-type thermoelectric element in the thermoelectric module. The inventor of the present application prepared N-type thermoelectric elements and P-type thermoelectric elements having different thermoelectric characteristics fabricated by various methods, made thermoelectric modules of various combinations thereof, and studied the heat absorbing characteristic and the temperature difference of the thermoelectric modules, thereby to obtain a finding that either the heat absorbing characteristic or the temperature difference of the thermoelectric modules can be improved by combining the N-type thermoelectric element and the P-type thermoelectric element that have different values of resistivity.

The thermoelectric module of one aspect of the present invention comprises a support substrate, the same number of N- and P-type thermoelectric elements disposed on the support substrate, a wiring conductor that connect the plurality of thermoelectric elements in series, and external connection terminals provided on the support substrate and electrically connected to the wiring conductor, wherein the N-type thermoelectric element and the P-type thermoelectric element have different values of resistivity. By making the resistivity different between the N-type thermoelectric element and the P-type thermoelectric element, it is made possible to improve either only the heat absorbing capacity or only the maximum temperature difference of the thermoelectric module.

In case it is desired to increase the maximum temperature difference of the thermoelectric module, for example, resistivity of the N-type thermoelectric element may be made lower than that of the P-type thermoelectric element. In this case, ratio of resistivity of the N-type thermoelectric element to that of the P-type thermoelectric element (N-type/P-type) is preferably in a range from 0.7 to 0.95.

In case it is desired to increase the heat absorbing capacity of the thermoelectric module, on the other hand, resistivity of the N-type thermoelectric element may be made higher than that of the P-type thermoelectric element. In this case, ratio of resistivity of the N-type thermoelectric element to that of the P-type thermoelectric element (N-type/P-type) is preferably in a range from 1.05 to 1.30.

It is preferable that the N-type thermoelectric element is made of a melt-formed material and the P-type thermoelectric element is made of a sintered material. This enables it to greatly improve the effect described above.

It is also preferable that power factor ((Seebeck coefficient)²/resistivity) of the P-type thermoelectric element and the N-type thermoelectric element is 4×10⁻³ W/mK² or higher. This enables it to achieve practically useful cooling characteristic.

Moreover, the N-type thermoelectric element is preferably a rod-shaped crystal made by unidirectional solidification. Use of the rod-shaped crystal for the N-type thermoelectric element improves the performance of the thermoelectric module further, and decreases the cost at the same time.

The P-type thermoelectric element is preferably made of a sintered material consisting of particles not larger than 50 μm. Use of the thermoelectric elements made of a sintered material of small particle size for the P-type thermoelectric element enables it to make a thermoelectric module that is excellent in either the heat absorbing capacity or in the temperature difference.

With the constitution described above, the thermoelectric module that is excellent either in the heat absorbing capacity or in the maximum temperature difference and is suitable for temperature control of semiconductor laser and the application to refrigerator can be obtained. However, these applications require high reliability which cannot be provided by the conventional thermoelectric module. Specifically, some of the conventional thermoelectric modules were broken with a low stress in shock test, or broken with a short life time in energization cycle test.

The inventors studied this phenomenon, and found that the thermoelectric modules that failed the reliability test included ones in which the wiring conductor and the thermoelectric elements were separated by a gap. Further investigation resulted in a finding that the gap can be easily generated when the thermoelectric element is displaced from the center of the wiring conductor. This displacement is caused by a clearance between an element alignment fixture and the element and by the surface tension of the solder. With the prior art technology, there have been such cases as the thermoelectric element was displaced to as far as near the edge of the wiring conductor. The inventor of the present application also found that the gap occurs from such causes as the edge of the wiring conductor located on the bonding surface of the thermoelectric element is tapered or shaped in arch of large radius of curvature, or is not flat, or thickness of the wiring conductor is not uniform.

Accordingly, the thermoelectric module of one aspect of the present invention is characterized by the cross sectional shape of the wiring conductor. Specifically, the cross section of the wiring conductor has such a shape as rectangular, or a trapezoid with the upper side located on the element bonding surface side is longer than the lower side located on the support substrate side. When the wiring conductor has the cross section of rectangular shape or a trapezoidal shape where the upper side located on the element bonding surface side is longer, a gap is less likely to be produced between the element and the wiring conductor even when the element is displaced from the center of the wiring conductor. Thus mechanical stress and thermal stress can be prevented from being concentrated at the junction, thereby making it possible to provide thermoelectric modules of high reliability and high stability with none of them failing from a low stress or in a short period of time during shock or energization test. The thermoelectric modules of further higher reliability and higher stability can be provided particularly by setting the angle between the element bonding surface and the side face adjacent thereto within 45 to 90° in the cross section of the wiring conductor.

Parallelism between the upper side and lower side of the wiring conductor on the element bonding surface is preferably within 0.1 mm. Flatness or the wiring conductor on the element bonding surface is preferably within 0.1 mm. This makes it possible to provide thermoelectric modules of high reliability and high stability.

The wiring conductor preferably contains at least one element selected from a group of Cu, Ag, Al, Ni, Pt and Pd as the main component. These materials have low electrical resistance and high thermal conductivity, and therefore generate less heat and provide better heat dissipation.

The wiring conductor is also preferably coated with a layer made of at least one element selected from a group of Sn, Ni and Au as the main component on the surface thereof. This improves the wettability with solder and achieves a joint having better electrical conductivity and bonding strength.

The wiring conductor is preferably formed by at least one method selected from among plating, metallization, DBC (Direct Bonding Copper) method and chip bonding method. This enables it to make the optimum wiring conductor in accordance with the required accuracy of the wiring pattern, current drawn and the cost.

There have been cases of performance deteriorating with time in the thermoelectric elements made of a material based on Bi—Te that has been preferably used in a thermoelectric module for electronic cooling purpose using the Peltier effect, when used for a long period of time at temperatures above 80° C. The inventor of the present application studied this phenomenon, and found that performance of the thermoelectric module deteriorates more quickly when a solder 10 that connects a lead member 5 (lead wire or block electrode) makes contact with the side face of the adjacent thermoelectric element 2 as shown in FIG. 5A and FIG. 5B. Further investigation showed that Sn contained in the solder and Te contained in the thermoelectric element react with each other thereby causing volume expansion and cracks in the thermoelectric element, thus eventually leading to breakage. It was also found that Diffusion of Sn component of the solder into the thermoelectric element leads to the loss of solder that bonds the lead wire, and failure to maintain the electrical connection.

Based on the findings described above, an aspect of the present invention provides a thermoelectric module having electrical connections of higher long-term reliability where reaction of the thermoelectric elements and the solder and the resultant deterioration are suppressed, by controlling the Sn content in the solder that bonds the lead member to the external connection terminal within a range from 12% to 40% by weight.

Void ratio in the thermoelectric element is preferably 10% or less. This restricts the reaction with the solder and improves the long-term reliability.

Further it is preferable that the thermoelectric element contains at least one kind of Bi and Sb and at least one kind of Te and Se, which enables it to achieve good cooling effect.

It is also preferable that the lead member is coated with a layer made of at least one element selected from a group of Sn, Ni, Au, Pt and Co on the surface thereof, since it improves the wettability with solder so as to achieve a joint having higher bonding strength when mounting the element in a package.

It is also preferable that bonding strength between the external connection terminal and the lead member is 2N or higher, since it eliminates such a trouble as the lead member comes off.

The process of electrically connecting the plurality of thermoelectric elements arranged on the support substrate and the process of bonding the external connection terminal and the lead member may be carried out either simultaneously or separately. When these processes are carried out separately, for example, the first process of electrically connecting the plurality of thermoelectric elements arranged on the support substrate and the second process of bonding the external connection terminal and the lead member are carried out successively. This enables it to bond the lead member by spot heating, and bond the lead member with a solder that is different from the solder used in bonding the thermoelectric elements. Reliability can be improved by using such a solder that reduces the reaction between the solder at the joint of the lead member and the element.

The thermoelectric module of the prior art has such a problem that the lead wire can easily come off when mounting the thermoelectric module in a package or the like, thus making a cause of low reliability. The inventor of the present application investigated this problem and found that there is variability in the bonding strength between the lead wire and the solder, including insufficient strength in some cases. It was also found that there is a diffusion layer of the lead member component formed from the lead wire toward the inside of the solder, and the diffusion layer is not formed sufficiently between the lead wire and the solder in a joint that has insufficient strength.

Accordingly, another aspect of the present invention provides a thermoelectric module of which external connection terminal has a diffusion layer of the lead member component having thickness of 0.1 μm or more formed in the solder that bonds the lead member with the external connection terminal, and the diffusion layer exists in 20% or more of the bonding area.

It is preferable that the interface between the diffusion layer of the lead member component and the non-diffusion layer has wavy shape. This increases the bonding strength further.

It is also preferable that the diffusion layer is denser than the surrounding non-diffusion layer, which enables it to provide a thermoelectric module that allows more stable mounting.

The lead member is preferably bonded at a temperature that is 103 to 130% of the melting point of the solder, which allows stable mounting.

The lead member may be a lead wire or a block electrode. Use of a block electrode as the lead member enables wire bonding, and makes it possible to easily automate the mounting operation and reduce the time required for the process.

In case a block electrode is bonded as the lead member by wire bonding, the wire is very thin and therefore as high resistance. Therefore, it is desirable to make the wire shorter, so as to reduce the power consumption and improve the reliability of the electrical connection. It is also necessary to improve the work efficiency of wire bonding operation.

Accordingly, further another aspect of the present invention provides a thermoelectric module comprising a lower support substrate, a plurality of thermoelectric elements disposed on the lower support substrate, an upper support substrate provided on the plurality of thermoelectric elements, a wiring conductor that electrically connects the plurality of thermoelectric elements with each other and external connection terminal that is provided on the upper support substrate and is electrically connected with the wiring conductor, wherein the external connection terminal has a planar electrode and a block electrode that is integrally provided in contact therewith.

This constitution makes it possible to make the wire shorter, so that the electrical resistance and the power consumption decrease. Since the block electrode enables it to make the profile lower, it can reduce the problems of breakage or bending of the electrode or peel-off of the joint during wire bonding and improve the yield of production. Also because the shock of wire bonding can be mitigated by the block electrode, yield of production and reliability can be improved.

When the shape, dimensions and material of the block electrode are selected properly, the electrical resistance can be set to a desired value and current-voltage characteristic of the thermoelectric module can be easily set. This feature, along with the reduction of wire length, contributes greatly to the reduction of electrical resistance of the wire and reduction in the power consumption.

It is preferable that the upper support substrate has via electrode so that the external connection terminal and the wiring conductor are electrically connected to each other with the via electrode. This enables it to easily provide the block electrode on the upper support substrate.

The via electrode is preferably formed right above the thermoelectric element. This improves the reliability of the electrical connection and reduces the energy loss due to heat generation.

Further, the block electrode is preferably a metal containing at least one element selected from among Zn, Al, Au, Ag, W, Ti, Fe, Cu, Ni and Mg. This enables it to provide the block electrode of lower resistance and lower power consumption.

Further it is preferable that the ratio of maximum diameter to height of the block electrode is in a range from 0.2 to 20. This constitution reduces the problems of breakage or bending of the electrode or peel-off of the joint during wire bonding, and makes it easier to improve the perpendicularity and straightness, thereby to improve the yield of production.

It is preferable that the melting temperature of the solder that bonds the planar electrode and the block electrode and the melting temperature of the solder that bonds the thermoelectric element and the wiring conductor are different. This makes it easier to assemble by taking advantage of the difference in the melting temperature of the solder.

Further, it is preferable that the planar electrode and the block electrode are integrated by localized heating. This enables it to easily provide the block electrode.

The block electrode is preferably coated with a thin layer made of at least one element selected from a group of Ni, Au, Sn, Pt and Co on the surface thereof. This improves the wettability with solder and achieves a joint having satisfactory bonding.

The package of the thermoelectric module according to the present invention has a container, electrode terminals provided in the container and the thermoelectric module described above, where the top surface of the block lead member and the electrode terminal are located preferably at substantially the same height. This enables it to minimize the wire length and makes the wire bonding operation easier.

### BRIEF DESCRIPTION OF THE DRAWINGS

FIG. 1 is a perspective view showing an example of thermoelectric module wherein lead member is a lead wire.

FIG. 2 is a perspective view showing an example of thermoelectric module wherein lead member is a block electrode.

FIGS. 3A and 3B are partially enlarged sectional views showing the joint between a thermoelectric element and a wiring conductor in the thermoelectric module according to one embodiment of the present invention.

FIG. 4A through 4C are partially enlarged sectional views showing the joint between thermoelectric elements and wiring conductor in the thermoelectric module of the prior art.

FIG. 5A is a partially enlarged view showing the structure near an external connection terminal of the thermoelectric module in case the lead member is a lead wire.

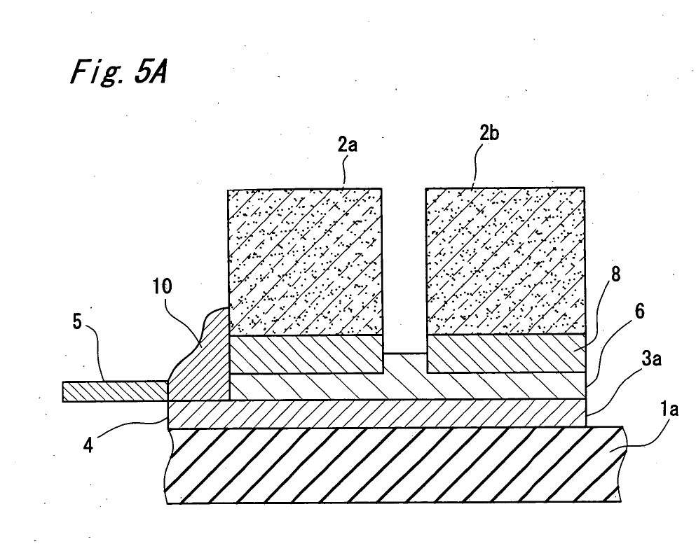

FIG. 5B is a partially enlarged view showing the structure near the external connection terminal of the thermoelectric module in case the lead member is a block electrode.

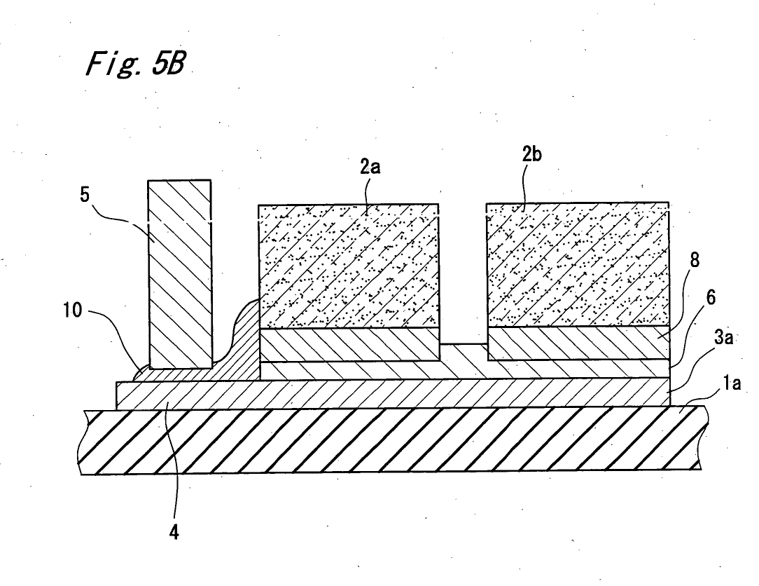

FIG. 6A is a partially enlarged sectional view showing the structure near the joint of lead member in case the lead member is a lead wire.

FIG. 6B is a partially enlarged sectional view showing the structure near the joint of lead member in case the lead member is a block electrode.

FIGS. 7A and 7B are perspective view and sectional view, respectively, showing the structure of the thermoelectric module according to one embodiment of the present invention.

FIG. 7C is a sectional view showing the thermoelectric module shown in FIGS. 7A and 7B mounted in a package.

### DESCRIPTION OF PREFERRED EMBODIMENTS

Now embodiments of the present invention will be described in detail below.

### Embodiment 1

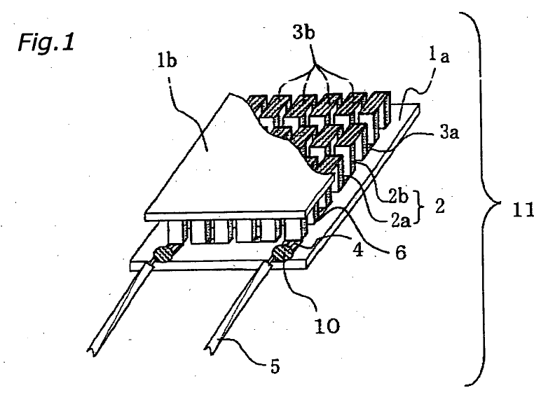

This embodiment is a thermoelectric module where a P-type thermoelectric element and an N-type thermoelectric element have different values of resistivity. A case where the lead member is a lead wire as shown in FIG. 1 will be described as an example.

The thermoelectric module shown in FIG. 1 comprises support substrates 1a, 1b made of ceramics such as alumina or an insulating resin, an N-type thermoelectric element 2a and a P-type thermoelectric element 2b that are disposed in the same numbers on the support substrates 1a, 1b, wiring conductors 3a, 3b that connect the plurality of thermoelectric elements in series with each other, and external connection terminal 4 provided on the support substrates 1a, 1b and are electrically connected to the wiring conductors 3a, 3b. The external connection terminal 4 can be connected with a lead wire 5 by means of solder 6. Power is supplied from the outside via the lead wire 5 connected to the external connection terminal 4.

There are two types of thermoelectric elements 2; the N-type thermoelectric element 2a and the P-type thermoelectric element 2b, disposed in matrix on one principal plane of the lower support substrate 1a. The N-type thermoelectric element 2a and the P-type thermoelectric element 2b are electrically connected in series by the wiring conductors 3a, 3b alternately such that N-type, P-type, N-type and P-type are arranged one on another, thereby to form an electric circuit. The thermoelectric element 2 is preferably made of a material based on Bi—Te that has the best thermoelectric performance at temperatures near the room temperature. This enables it to achieve good cooling effect. It is preferable to use Bi_{0.4}Sb_{1.6}Te₃, Bi_{0.5}Sb_{1.5}Te₃ or the like as the P-type, and Bi₂Te_{2.85}Se_{0.15}, Bi₂Te_{2.9}Se_{0.1} or the like as the N-type.

N-type and P-type thermoelectric elements can be manufactured by substantially the same method as the prior art method. For example, the thermoelectric element can be made by slicing the thermoelectric material along a direction of interposing the thermoelectric material in the thermoelectric module, coating the surface with Ni, and further Au or the like by plating for improving the solderability and cutting the material to a desired shape.

The thermoelectric module of this embodiment is characterized in that the N-type thermoelectric element 2a and the P-type thermoelectric element 2b have different values of resistivity. Resistivity of the N- and P-type thermoelectric element can be controlled, for example, by the following method. Resistivity can be controlled by applying a pressure when making the element, or by changing the crystal orientation in forming it in a single crystal. For example, higher the pressure during pressurization of a sintered body is, lower the resistivity of thermoelectric element becomes. A resistivity of thermoelectric element in a parallel direction is smaller by about one order than that in a perpendicular direction to the C plane of crystals. Therefore, a resistivity of thermoelectric can be controlled to be small by controlling a crystal growing of a single-crystal thermoelectric element so that C plane of the crystal will be parallel to the growing direction of crystals. In the case of the N-type thermoelectric element 2a, a resistivity of the element can be controlled by changing the concentration of additive halogen element such as iodine or bromine. In the case of the P-type thermoelectric element 2b, a resistivity of the element can be controlled by changing the concentration of additive element such as Te or Se. In case resistivity is controlled by changing the concentration of the additive element, resistivity increases when the concentration of the additive element is lower.

When the N-type thermoelectric element 2a and the P-type thermoelectric element 2b are formed with different values of resistivity, either the heat absorbing capacity or the temperature difference of the thermoelectric module can be remarkably increased in comparison to the case where both thermoelectric elements have the same value of resistivity. The expression “different values of resistivity” here means that there is a significant level instrument in the resistivity of the thermoelectric material measured by four-probe analysis method. According to the present invention, the N-type thermoelectric element 2a and the P-type thermoelectric element 2b are said to have “different” values of resistivity when the difference is 5% or greater.

While there is no clear explanation for why either the heat absorbing capacity or the temperature difference of the thermoelectric module can be improved by differentiating the resistivity, it is supposed to be caused by the following mechanism.

The carrier that transfers heat in the thermoelectric material is electron in the N-type thermoelectric element 2a, and is hole in the P-type thermoelectric element 2b. Movement of holes is an apparent movement, and actually electrons move in a direction opposite to the direction of heat transfer in the P-type thermoelectric element 2b. Therefore, when power is supplied to the thermoelectric module, while heat is transferred in the direction of electron movement in the N-type thermoelectric element 2a, the direction of heat transfer in the P-type thermoelectric element 2b is opposite to the electron movement. Since electrons function as the heat carrier, heat transfer in the thermoelectric module is supposed to be governed by the heat transfer in the N-type thermoelectric element 2a.

In case the N-type thermoelectric element 2a has a resistivity higher than that of the P-type thermoelectric element 2b or, in other words, electrical conductivity of the P-type thermoelectric element 2b is higher than that of the N-type thermoelectric element 2a, it is considered that the carrier concentration is lower in the N-type thermoelectric element 2a than in the P-type thermoelectric element 2b. This leads to a higher electromotive force, namely higher Seebeck coefficient, in the N-type thermoelectric element 2a. Since the heat absorbing capacity of the thermoelectric module is governed by the Seebeck coefficient, the heat absorbing capacity of the thermoelectric module can be increased in comparison to the case where the P-type thermoelectric element 2b and the N-type thermoelectric element 2a have the same value of resistivity.

In case the N-type thermoelectric element 2a has a resistivity lower than that of the P-type thermoelectric element 2b, on the other hand, it is considered that the carrier concentration is higher in the N-type thermoelectric element 2a than in the P-type thermoelectric element 2b. Thus Joule heating in the N-type thermoelectric element 2a is suppressed, so that greater temperature difference can be achieved than in the case where the P-type thermoelectric element 2b and the N-type thermoelectric element 2a have the same value of resistivity.

Therefore, in order to make the maximum temperature difference larger in this embodiment, it is preferable to control the ratio of resistivity of the N-type thermoelectric element 2a to that of the P-type thermoelectric element 2b (N-type/P-type) in a range from 0.7 to 0.95. Within this range, carrier concentration in the N-type thermoelectric element 2a can be increased, and accordingly temperature difference in the thermoelectric module can be increased. The ratio is more preferably 0.90 or lower, or 0.85 or lower, in order to increase the temperature difference. When the ratio of resistivity is lower than 0.7, the effect described above cannot be achieved since the difference in resistivity is too large. Ratio of resistivity higher than 0.95 results in insufficient effect of increasing the temperature difference and is therefore not desirable. The temperature difference here refers to the temperature difference between the cooling surface and the heating surface of the thermoelectric module while the heating surface is kept at a constant temperature, and can be made larger by 0.1° C. or more than in the case where the P-type thermoelectric element 2b and the N-type thermoelectric element 2a have the same value of resistivity, according to the present invention.

In order to increase the heat absorbing capacity, it is preferable to control the ratio of resistivity of the N-type thermoelectric element 2a to that of the P-type thermoelectric element 2b (N-type/P-type) in a range from 1.05 to 1.30. Within this range, carrier concentration in the N-type thermoelectric element 2a can be decreased, and accordingly heat absorbing capacity of the thermoelectric module can be increased. The ratio is more preferably 1.10 or higher, or 1.15 or higher, in order to increase the heat absorbing capacity. When the ratio of resistivity is higher than 1.30, the effect described above cannot be achieved since the difference in resistivity is too large. Ratio of resistivity lower than 1.05 results in insufficient effect of increasing the heat absorbing capacity and is therefore not desirable. The heat absorbing capacity refers to the amount of heat applied to the cooling surface till the temperatures of the cooling surface and the heating surface become the same level after supplying power to the thermoelectric module so that the largest temperature difference is achieved between the cooling surface and the heating surface while keeping the heating surface at a constant temperature. Heat absorbing capacity can be measured by using a heater or the like having the same shape as the cooling surface. According to the present invention, heat absorbing capacity can be increased by 5% or more in comparison to the case where the P-type thermoelectric element 2b and the N-type thermoelectric element 2a have the same value of resistivity.

It is preferable that the same number of N-type thermoelectric elements 2a and P-type thermoelectric elements 2b are provided and are connected in series. In the thermoelectric module, the N-type thermoelectric element 2a and the P-type thermoelectric element 2b function together in a pair. When the numbers of the N-type thermoelectric elements and the P-type thermoelectric elements are not equal, there is an element that does not contribute to cooling, resulting greater Joule heating and lower cooling performance. When the N-type thermoelectric elements and the P-type thermoelectric elements are not connected in series, wiring for the connection becomes longer and complicated. Thus Joule heating increases also when the N-type thermoelectric elements and the P-type thermoelectric elements are not connected in series, which is not desirable.

While the thermoelectric elements may have various sizes depending on the required cooling performance, appropriate size for an ordinary application is from 0.4 to 2.0 mm in length and width, and from 0.3 to 3.0 mm in height. Length of the electrode is preferably from 1.5 to 2.0 times the length of the element, in order to obtain satisfactory performance. In order to make a compact thermoelectric module 11, it is preferable to prepare thermoelectric elements that have been machined to sizes in a range from 0.1 to 2 mm in length, from 0.1 to 2 mm in width and from 0.1 to 3 mm in height.

It is also preferable that power factor ((Seebeck coefficient)²/resistivity) of the N-type thermoelectric element 2a and the P-type thermoelectric element 2b is 4×10⁻³ W/mK² or higher. The higher the power factor, the higher the performance index, and the effect of the present invention becomes higher when the power factor is 4 or higher. An element that has power factor lower than 4 is practically useful, although the thermoelectric module has significantly lower performance.

Now a method of manufacturing the thermoelectric module according to this embodiment will be described below. First, the thermoelectric elements 2 are prepared. As described above, the N-type thermoelectric element and the P-type thermoelectric element of this embodiment are made to have difference values of resistivity. The N-type thermoelectric element and the P-type thermoelectric element made by a known method can be used. Specifically, crystals made by sintering or melt-freeze method can be used.

According to this embodiment, it is preferable to combine the N-type thermoelectric element 2a made by melt-freeze method and the P-type thermoelectric element 2b made by sintering method. When the N-type thermoelectric element 2a consists of a material made by melt-freeze method, diffusing effect of the grain boundary in the N-type thermoelectric element 2a on the electron mobility becomes small and, as a result, the desired effect described above increases. In the present invention, the melt-formed material refers to materials in general that are made by melting an alloy and then frozen by cooling, and contains single crystal grown by unidirectional solidification process or the like. The sintered material refers to polycrystalline materials in general that are made by crushing melt-formed material into powder, and sintering the crushed powder while compressing it by hot press or the like.

It is particularly preferable to make the N-type thermoelectric element from a rod-shaped crystal grown by unidirectional solidification method, among the melt-formed materials. Use of the material made by unidirectional solidification for the N-type thermoelectric element 2a enables it to achieve a very high performance of the thermoelectric module, while increasing the effect of improving the cooling performance of the thermoelectric module. Use of the rod-shaped crystal decreases the number of cutting processes, thus mitigating the decrease in the yield of production that is a drawback of the melt-formed material.

The P-type thermoelectric element 2b is preferably made of a sintered material consisting of particles not larger than 50 μm. Use of the material consisting of particles not larger than 50 μm causes remarkable decrease in the heat conductivity. When the P-type sintered material having low heat conductivity is combined with an N-type melt-formed material, difference in electron mobility can be made greater due to the difference in heat conductivity, and greater effect of the difference in resistivity can be achieved. It is more preferable that the P-type thermoelectric element 2b is made of a sintered material consisting of particles not larger than 30 μm. A sintered material consisting of such small particles has high strength so that reliability of the thermoelectric module can be improved further.

Then a support substrate 1 made of ceramics such as alumina, aluminum nitride, silicon nitride, silicon carbide, diamond or the like is prepared. After forming the material in the shape of substrate, wiring conductor 3 and external connection terminal 4 are formed on the surface from electrically conductive material such as Zn, Al, Au, Ag, W, Ti, Fe, Cu, Ni, Pt, Pd and Mg. The wiring conductor 3 and external connection terminal 4 can be formed by plating, metallization, DBC (Direct Bonding Copper) method or chip bonding method. The wiring conductor 3 is preferably coated with a coating layer 7 made of at least one element selected from a group of Ni, Au, Sn, Pt and Co on the surface thereof, so as to improves the wettability of solder 6.

Then the thermoelectric elements 2 are arranged on the wiring conductor 3. The thermoelectric elements are metallized with Ni or the like on the bonding surface in advance, in order to improves the wettability of solder 6. The metallized layer is bonded with the wiring conductor 3 by means of the solder 6. The thermoelectric elements 2 are disposed so that the N-type thermoelectric element 2a and the P-type thermoelectric element 2b are arranged alternately and are electrically connected in series.

The lead wires 5 having thickness of 0.3 mm is bonded by local heating with soft beam or the like to the external connection terminal 4 of the thermoelectric module 11 made as described above. Alternatively, the lead wires 5 and the external connection terminal 4 may be spot-welded by YAG laser or the like.

The thermoelectric module wherein the N-type thermoelectric element 2a and the P-type thermoelectric element 2b have different values of resistivity, made as described above, can have either the temperature difference or heat absorbing capacity remarkably improved in comparison to the thermoelectric module where both elements have the same resistivity. As a result, the thermoelectric module of this embodiment is promising for such applications as cooling of laser diode that requires strict temperature control, semiconductor wafer cooling plate, home refrigerator that requires larger heat absorbing capacity, and air conditioner.

### Embodiment 2

The thermoelectric module of this embodiment is a variation of the thermoelectric module of the first embodiment where the wiring conductor is formed in a predetermined shape so as to further improve the reliability of the thermoelectric module. With other respects, this embodiment is similar to the first embodiment.

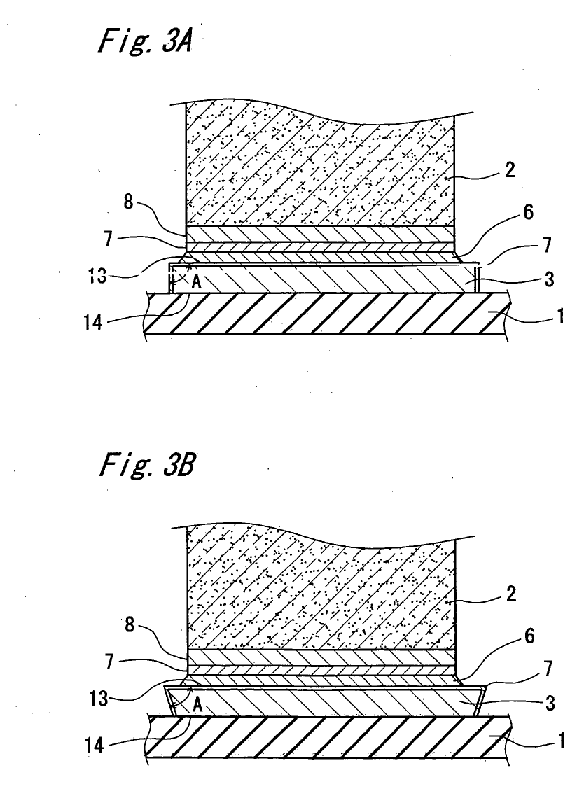

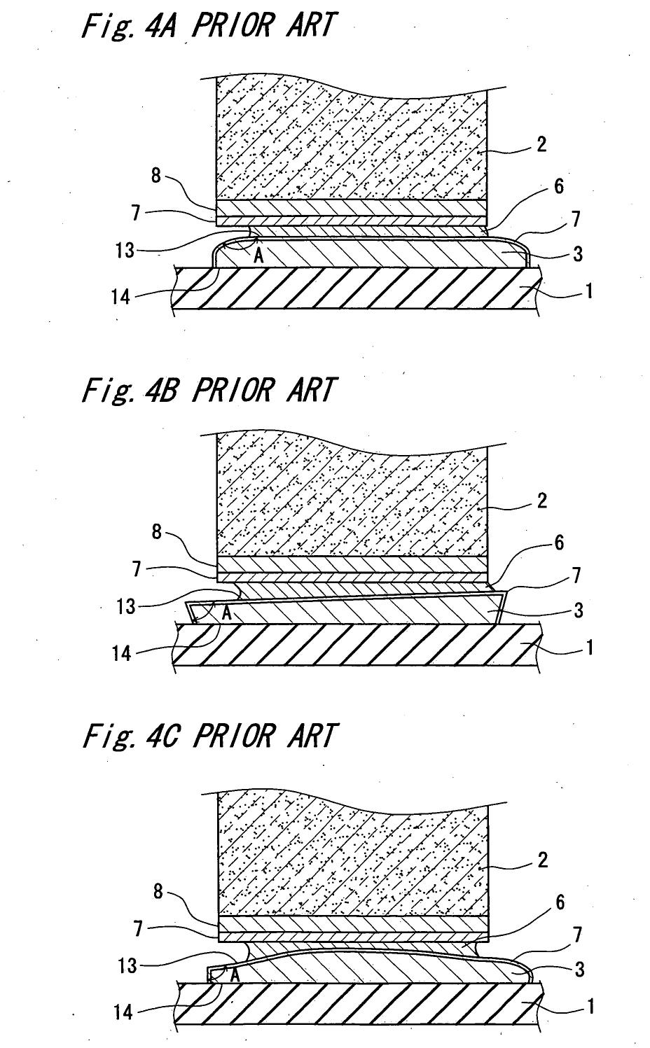

In the prior art, there has been the wiring conductor 3 having D-shaped cross section as shown in FIG. 4A. As a consequence, when the thermoelectric elements 2 is displaced from the center of the wiring conductor 3, a gap is formed between the bottom surface of the thermoelectric elements 2 and the top surface of the wiring conductor 3 (element bonding surface), resulting in lower reliability. According to this embodiment, to counter the problem described above, the wiring conductor 3 is formed so as to have a cross section of rectangular, square or trapezoidal shape which is longer on the element bonding surface side (inverted trapezoid). FIG. 3A shows a case where the wiring conductor has rectangular cross section, and FIG. 3B shows a case where the wiring conductor has inverted trapezoidal cross section. With this configuration, since a gap is not formed between the thermoelectric elements 2 and the wiring conductor 3 even when the thermoelectric element 2 is displaced from the center of the wiring conductor 3, thereby preventing mechanical or thermal stress from being concentrated there. As a result, thermoelectric modules of high reliability and high stability can be made without any unit failing from a low stress or in a short period of time during shock or energization test.

When the wiring conductor 3 is formed with a cross section of inverted trapezoidal shape as shown in FIG. 3B, there are such benefits as described below. The wiring conductor 3 having the inverted trapezoidal cross section has a greater contact area with the thermoelectric element 2 while keeping the contact area between the wiring conductor 3 and the support substrate 1 small. When the wiring conductor 3 and the thermoelectric element 2 have a larger contact area with each other, a gap can be prevented from being formed between the thermoelectric element 2 and the wiring conductor 3 even when the thermoelectric element 2 is displaced to some extent. When the contact area between the wiring conductor 3 and the support substrate 1 is small, warping can be suppressed from being caused due to the difference in thermal expansion coefficient between the wiring conductor 3 and the support substrate 1. As a result, the thermoelectric module having higher reliability can be made by forming the wiring conductor 3 to have an inverted trapezoidal cross section.

The wiring conductor 3 preferably has such a cross section as the angle between the element bonding surface 13 and the side face adjacent thereto is in a range from 45 to 90°. This configuration enables it to obtain a stable thermoelectric module having high reliability for the same reason described previously. When the angle between the element bonding surface 13 and the side face adjacent thereto is larger than 90°, a gap tends to be caused when the thermoelectric elements 2 is displaced. When the angle is smaller than 45°, chipping at the edge tends to occur which may cause cracks in the thermoelectric elements 2 or in the interface of joint. The angle is preferably in a range from 60 to 90°, more preferable from 70 to 90°. It is allowable that edges of wiring conductors are R-shaped with curvature radius smaller than 0.05 mm, or are composed of C plane with a size smaller than 0.05 mm.

In the prior art, there may be such cases where thickness of the wiring conductor 3 is graded as shown in FIG. 4B. This results in a gap formed between the bottom surface of the thermoelectric elements 2 and the top surface 13 of the wiring conductor 3 (element bonding surface), resulting in lower reliability. According to this embodiment, to counter this problem, parallelism between the element bonding surface 13 and the support substrate bonding surface 14 of the wiring conductor 3 is controlled within 0.1 mm. When deviation from parallelism is larger than 0.1 mm, the element bonding surface is significantly inclined with respect to the thermoelectric elements 2, which often results in a gap formed between the thermoelectric elements 2 and the bonding surface of the wiring conductor 3. This may cause failure from a low stress or in a short period of time during shock or energization test. Parallelism is preferably within 0.05 mm, and more preferably within 0.03 mm. Here, the word “parallelism” of the wiring conductor 3 means a difference (A−B) between a gap formed between the element-bonding surface 13 and the supporting-substrate-bonding surface in a cross-section at one end of the wiring conductor 3 (=A) and a corresponding gap at another end of the wiring conductor 3 (=B).

In the prior art, there have been such cases where the wiring conductor 3 has uneven surface as shown in FIG. 4C. This causes a gap formed between the thermoelectric element 2 and the bonding surface of the wiring conductor 3, thus resulting in low reliability. In this embodiment, flatness of the element bonding surface of the wiring conductor 3 is controlled within 0.1 mm. When deviation from flatness is larger than 0.1 mm, a gap is likely to be formed between the thermoelectric elements 2 and the bonding surface of the wiring conductor 3. This may cause failure from a low stress or in a short period of time during shock or energization test. Flatness is preferably within 0.05 mm, and more preferably within 0.03 mm. Here the word “flatness” means a difference between maximum and minimum gap, each gap being formed between the element-bonding surface 13 and the supporting-substrate-bonding surface in a cross-section of the wiring conductor 3.

The wiring conductor 3 is for supplying power to the thermoelectric elements 2, and is preferably made of a metal containing at least one element selected from among Zn, Al, Au, Ag, W, Ti, Fe, Cu, Ni, Pt, Pd and Mg. These metals have low electrical resistance and high electrical conductivity, and are therefore better in minimizing heat generation and dissipating heat. Among these, Cu, Ag, Al, Ni, Pt and Pd are particularly preferable for the reasons of electrical resistance, electrical conductivity and cost.

The wiring conductor 3 may be coated with a coating layer 7 made of at least one element selected from a group of Ni, Au, Sn, Pt and Co so as to improve the wettability of the solder 6. The coating layer 7 may be formed by plating, and achieves a joint having better electrical conductivity and bonding strength. Among the metals, Ni, Au and Sn are particularly preferably used for the reasons of better bonding and wettability of solder.

The wiring conductor 3 is preferably formed by at least one method selected from among plating, metallization, DBC (Direct Bonding Copper) method and chip bonding method. This enables it to make the optimum wiring conductor 3 in accordance with the accuracy of the wiring pattern, current drawn and the cost. Different methods of forming the wiring conductor have individual features, which may be utilized according to the purpose. For example, plating or metallization may be employed for the wiring conductor having thickness not larger than 100 μm, and DBC method or chip bonding method may be used for wiring conductor having larger thickness.

For example, the wiring conductor may be formed as follows: First, a cupper plate of 0.5 to 1 mm thickness is formed on an insulating substrate by means of bonding or the like. Next, a novolac-resin-based masking agent is applied in a patterned form on the cupper plate by, e.g., screen printing. Then, the substrate is immersed in a nitrate solution or a mixed solution of nitrate and sulfuric acid of equivalent concentration around five, where the cupper layer is etched at 80 to 100° C. for two to four hours. The masking agent is removed by an organic solvent like acetone to form the wiring conductor. The parallelism or flatness of the wiring conductor may be controlled by polishing the cupper plate before the etching process. Alternatively, the parallelism or flatness may be controlled by pressing the cupper plate after the etching process. In order to make a cross section of the wiring conductor be reverse-trapezoid, a high etching rate is preferable. That is, if the temperature during etching is too low or the concentration of etching solution is too small, a reverse-trapezoid cross section can hardly be obtained regardless of the etching time. The longer the etching duration is, the larger the taper angle of reverse-trapezoid cross section will be.

The wiring conductor 3 formed on the support substrate 1 as described above eliminates any unit that fails from a low stress or in a short period of time during shock or energization test. Use of such a support substrate to make the thermoelectric module 11 improves the reliability of the thermoelectric module and stabilizes it.

Since the thermoelectric module of this embodiment has the wiring conductor 3 of which shape is controlled, there occurs no unit that rails from a low stress or in a short period of time during shock or energization test. As a result, the thermoelectric module having high long-term stability can be provided.

### Embodiment 3

This embodiment is a variation of the thermoelectric module of the first or second embodiment where composition of the solder 10 that connects the lead member 5 with the external connection terminal is controlled so as to improve the reliability of the thermoelectric module further. With other respects, this embodiment is similar to the first and second embodiment.

In this embodiment, Sn content in the solder 10 that connects the lead member 5 with the external connection terminal is controlled in a range from 12% to 40% by weight. There are no restrictions on the content of other component, as long as the Sn content is within this range. When the Sn content is less than 12% by weight, melting point of the solder becomes too high which results in melting or deterioration of the element, thus making it impossible to make a good joint. When the Sn content is higher than 40% by weight, the higher proportion of Sn in the solder increases the possibility of reaction with the thermoelectric element. Sn content is preferably in a range from 15% to 30% by weight, more preferably in a range from 18% to 25% by weight. Particularly preferable composition or the solder is 80% by weight of Au and 20% by weight of Sn. Composition of the solder can be analyzed by X-ray microanalysis (EPMA).

In this embodiment, void ratio of the thermoelectric element 2 is 10% or less, preferably 7% or less and more preferably 5% or less. When void ratio of the thermoelectric element is higher than 10%, component of the solder diffuses more quickly and the reaction area increases, thus increasing the possibility of reaction. While there is no limitation on the material of the thermoelectric element as long as the void ratio is in the range described above, a material based on Bi—Te is preferably used for the reason of high cooling capacity. Void ratio can be measured by Archimedes method. Void ratio of thermoelectric element can be controlled by a sintering temperature. That is, when you make a sintering temperature lower, void ration will decrease.

The wiring conductor 3 and the external connection terminal 4 are provided for supplying power to the thermoelectric elements 2. In this embodiment, it is preferable to use a metal of low electrical resistance and high electrical conductivity such as Cu, Al or Au in order to minimize the heat generation and achieve high heat dissipation.

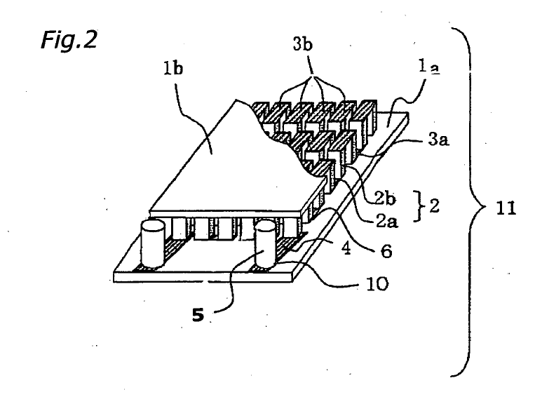

The lead wire 5 shown in FIG. 1 may be replaced with a block electrode 5. This makes it possible to connect the thermoelectric module with the outside by wire bonding, easily automate the operation of mounting the thermoelectric module and reduce the time required for the work. When the top surface of the block electrode 5 and the electrode terminal of the package in which the thermoelectric module is to be mounted are set to the same height, the distance of moving the wire during wire bonding operation can be minimized thereby reducing the time required in wire bonding. Configuration of the block electrode 5 may be a prism having triangular, rectangular, hexagonal or octagonal cross section, or a cylinder. Among these shapes, rectangular prism is preferable for the reason of positioning accuracy and the cross sectional area. When emphasis is placed on the ease of forming, ease of machining, dimensional accuracy and cost, cylinder is preferable. FIG. 2 shows a case of cylinder.

When the bonding strength between the lead wire 5 or the block electrode 5 and the external connection terminal is less than 2N, there is a high probability that the lead or the electrode comes off during the work to bond onto the package. Therefore, the bonding strength is preferably 2N or higher, more preferably 5N or higher and most preferably 10N or higher. This eliminates such a trouble as the lead wire or the block electrode 5 comes off during the work to bond the thermoelectric module onto the package. In order to improve the bonding strength, it is important to improve the wettability of the solder with the electrode by using a flux or the like, and to cover the joint of the lead wire 5 or the block electrode 5 completely with the solder.

While there are no limitation on the material used to make the wiring conductor 3, the external connection terminal 4, the lead wire 5 and the external connection terminal 7 as long as the material has electrical conductivity so as to allow current to flow easily, it is preferably made of a metal containing at least one element selected from among Zn, Al, Au, Ag, W, Ti, Fe, Cu, Ni and Mg. When the lead wire 5 or the block electrode 5 is coated with a coating layer made of at least one element selected from a group of Ni, Au, Sn, Pt and Co by plating or the like on the surface thereof, wettability of the solder 10 can be improved and better electrical conductivity and higher bonding strength can be achieved. This results in higher bonding strength when mounting the thermoelectric module 11 in a package or the like.

Bonding of the lead member 5 and the external connection terminal 4 may be carried out at the same time as the bonding of the thermoelectric elements 2 and the wiring conductor 3 by using a reflow furnace or the like, thereby to shorten and simplify the process. When the process of bonding the lead member 5 and the external connection terminal 4 is carried out separately from the bonding of the thermoelectric elements 2 and the wiring conductor 3, solders having different melting points can be used in both processes.

In the thermoelectric module of this embodiment, since reactivity between the thermoelectric element and the solder can be kept low, the thermoelectric module having high long-term stability can be provided.

### Embodiment 4

This embodiment is a variation of the thermoelectric module of the first through third embodiments where a diffusion layer 8 of the lead member 5 having a predetermined extent is formed in the solder 10 that connects the lead member 5. With other respects, this embodiment is similar to the first through third embodiments.

In the thermoelectric module 11 shown in FIG. 1 or FIG. 2, the lead member 5 and the external connection terminal 4 are electrically connected so as to form an electric circuit as the lead member 5 that supplies power makes contact with the solder 10, in the prior art. However, although electrical joint is made, the joint has weak mechanical strength. As a result, there has been such a case as the lead wire 5 comes off during the operation of bonding the thermoelectric module 11 onto the package, thus disabling stable mounting.

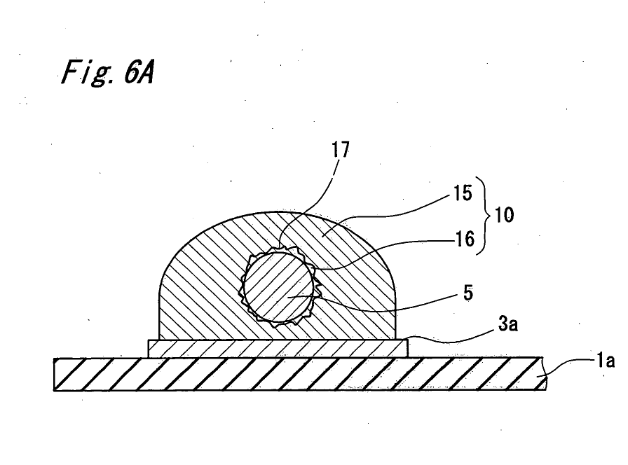

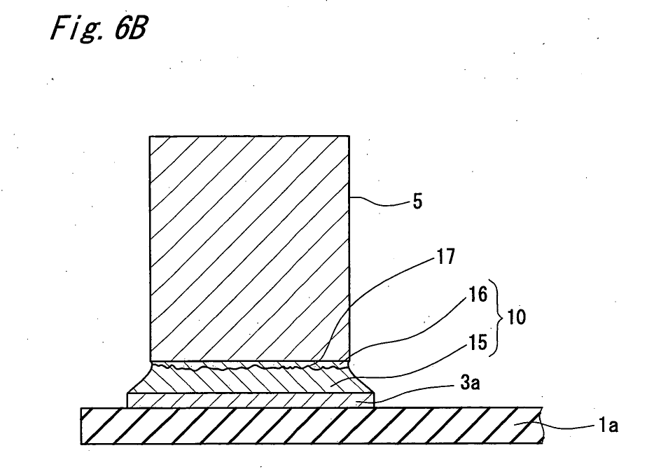

In this embodiment, a diffusion layer 16 of the component of the lead member is formed, to a thickness of 0.1 μm or more and to an extent of 20% or more in the ratio of area to the bonding surface, in the solder 10 that bonds the lead member 5 to the external connection terminal 4, as shown in FIG. 6A or FIG. 6B. FIG. 6A shows a case where the lead member 5 is a lead wire, and FIG. 6B shows a case where the lead member 5 is a block electrode. With this constitution, anchoring effect is generated between the solder 10 and the lead member 5, so as to increase the mechanical strength. As a result, the thermoelectric module that enables stable mounting operation can be provided where the lead member does not come off during the mounting process. When the diffusion layer 16 of the component of the lead member is formed to a thickness less than 0.1 μm or to an extent less than 20% of area of the bonding surface, sufficient anchoring effect and bonding strength cannot be obtained. Thickness is preferably 0.3 μm or larger, and more preferably 0.5 μm or larger. Ratio of the area of the diffusion layer 16 to the area of the bonding surface is preferably 30% or more, and more preferably 40% or more.

It is important that the bonding strength between the lead member 5 that supplies power and the solder 10 is 2N or higher. This eliminates the trouble of the lead member 5 coming off during the mounting operation, thus enabling stable mounting operation. The bonding strength is preferably 5N or higher, and more preferably 10N or higher. When the bonding strength is lower than 2N, there have been such cases as the lead member comes off during the mounting operation.

It is preferable that the interface 17 between the diffusion layer 16 of the lead member component and the non-diffusion layer 15 has a wavy shape. This provides more secure anchoring effect and stable bonding strength further. The interface 17 between the diffusion layer 16 and the non-diffusion layer 15 can be investigated by cutting the joint and analyzing the components of the lead member in the section by X-ray microanalysis, and mapping the components. The diffusion layer 16 is defined as a region in the solder 10 where the component of the lead member is contained by 1 at % or more.

It is also preferable that the diffusion layer 16 is denser than the surrounding non-diffusion layer 15. This enables it to achieve higher and more stable bonding strength than in the case where the non-diffusion layer 15 is denser than the diffusion layer. Denseness of the diffusion layer 16 and the non-diffusion layer 15 can be studied by observing the cut surface of the joint by SEM with a magnifying factor of 100 to 3000 times, and determining the proportion of the sectional area or a region near the interface occupied by the voids. The smaller the area occupied by the voids in the unit area, the denser the material.

In this embodiment, formation of the diffusion layer 8 in the solder 10 can be controlled by the bonding temperature. Specifically, by bonding the lead member 5 and the solder 10 at a temperature that is 103 to 130% of the melting point of the solder 10, the diffusion layer 16 of the lead member component can be formed in the solder 10. In case the solder 10 is melted at a temperature lower than 103% of the melting point for bonding, the diffusion layer 8 of the component of the power supplying wire cannot be formed and stable bonding strength cannot be obtained. In case the solder 10 is melted at a temperature higher than 130% of the melting point for bonding, on the other hand, viscosity of the solder becomes too low with excessive fluidity which may cause the solder to flow onto the wiring conductor 3 leading to short-circuiting. Therefore, it is preferable to make the solder joint by melting the solder 10 at a temperature in a range from 103 to 130%, more preferably from 105 to 125% and most preferably from 107 to 120% of the melting point. Moreover, it is preferable to set the cooling rate to an adequate speed.

Thus this embodiment provides the thermoelectric module 11 that is very easy to mount, since the lead member 5 that supplies power does not come off when mounting the thermoelectric module onto a package.

### Embodiment 5

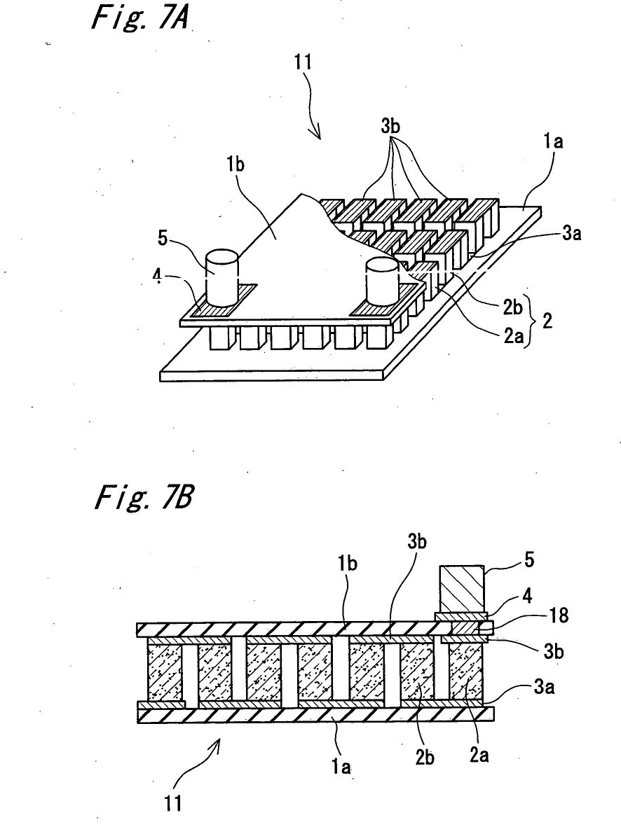

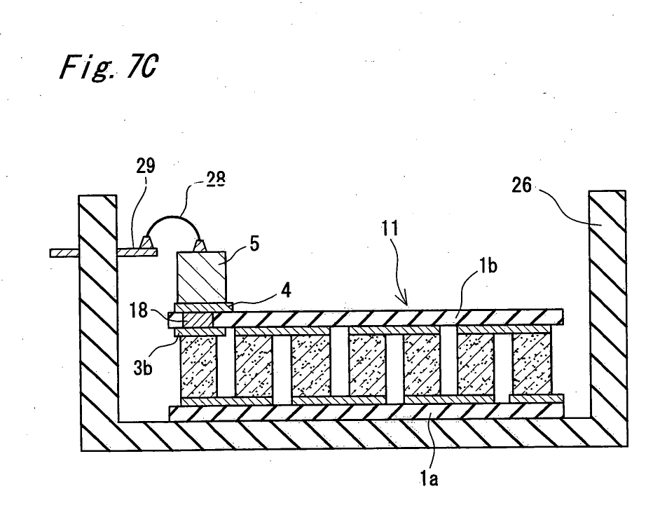

This embodiment is a variation of the thermoelectric module of the first through fourth embodiment, wherein the electrode structure that is best suited to wire bonding. FIG. 7A shows a perspective view and FIG. 7B shows a sectional view of the thermoelectric module according to this embodiment. In the thermoelectric module shown in FIGS. 7A and 7B, as in the case of the thermoelectric module of the first through fourth embodiment, the lower support substrate 1a and the upper support substrate 1b interpose the plurality of thermoelectric elements 2 that comprise the N-type thermoelectric element 2a and the P-type thermoelectric element 2b. The N-type thermoelectric element 2a and the P-type thermoelectric element 2b are provided on the support substrates 1a, 1b via the wiring conductors 3a, 3b connected in series by the wiring conductors 3a, 3b.

As shown in FIGS. 7A and 7B, the external connection terminal 4 is provided on the top surface of the upper support substrate 1b, namely on the surface opposite to the surface where the thermoelectric elements 2 is bonded. The block electrode 5 is integrally bonded to the external connection terminal 4. That is, the planar external connection terminal 4 is provided on the upper support substrate 1b and the block electrode 5 is provided integrally so as to contact therewith.

The external connection terminal 4 and the wiring conductor 3 are disposed to oppose each other while interposing the upper support substrate 1b. There is no limitation to the method of connecting the external connection terminal 4 and the wiring conductor 3. For example, the external connection terminal 4 and the wiring conductor 3 may be connected by providing a wiring around the upper support substrate 1b. However, since the wiring is located at the edge of the upper support substrate with this method, electrical connection may become unstable as the support substrate is chipped or the wiring is worn.

Therefore it is preferable that the wiring conductor 3b provided on the bottom surface of the upper support substrate 1b and the planar electrode 4 provided on the top surface are connected with each other via the via electrode 18 formed in the upper support substrate 1b, as shown in FIG. 7B. Wiring by means of the via electrode 18 enables it to significantly improve the reliability, especially the long-term reliability of the connection since there is very small chance of the via electrode to be chipped or worn. Especially as the via electrode 18 is disposed right above the thermoelectric element 2 so that the thermoelectric element 2 and the planar electrode 4 are connected through the shortest path, and electrical resistance in the thermoelectric module can be decreased, thus contributing to energy saving. With the method of the prior art (for example, Japanese Unexamined Patent Publication (Kokai) No. 11-54806), since the substrate warps during wire bonding, there has been such a problem that cracks occur between the thermoelectric element 2 and the wiring conductors 3a, 3b. With the structure of this embodiment, in contrast, the problem can be mitigated so as to further improve the yield of production and reliability of the thermoelectric module.

As will be seen from the foregoing description, electrical connection with the outside can be easily established by forming the planar electrode 4 on the top surface of the upper support substrate 1b and forming the block electrode 5 integrally with the planar electrode 4. For example, current can be supplied to the thermoelectric module 11 by mounting the thermoelectric module 11 shown in FIGS. 7A and 7B in a package 26 such as semiconductor laser, and connecting the block electrode 5 provided on the thermoelectric module 11 with the electrode terminal 29 and the wire 28 that are provided in the package 26.

The planar electrode 4 is for supplying power to the thermoelectric elements 2, and is preferably made of a metal that has low electrical resistance and high electrical conductivity such as Cu, Al or Au. This constitution suppresses the heat generation from the thermoelectric module and improves the dissipation of heat.

Configuration of the block electrode 5 may be a prism having triangular, rectangular, hexagonal or octagonal cross section, or a cylinder. Among these shapes, rectangular prism is preferable for the reason of positioning accuracy and the cross sectional area. When emphasis is placed on the ease of forming, ease of machining, dimensional accuracy and cost, cylinder is preferable. FIG. 7A shows a case of cylinder.

The block electrode is preferably made of a metal containing at least one element selected from among Zn, Al, Au, Ag, W, Ti, Fe, Cu, Ni and Mg, for the reason of low electrical resistance. These metals have sufficient strength to endure the shock during wire bonding and proper resilience to absorb the shock, and are therefore preferably used to form the block electrode.

The ratio d/h of maximum width d to height h of the block electrode is preferably in a range from 0.2 to 20, more preferably from 0.5 to 15 and most preferably from 1 to 10. The maximum width d of the block electrode corresponds to the diameter in the case of cylinder, major axis in the case of ellipse or longer diagonal in the case of prism. This configuration reduces the troubles of breakage or bending of the electrode, thus making it easier to dispose vertically, thus making contributions to the size reduction of the package and the thermoelectric module and to the improvement of the yield of production.

In case the block electrode 5 is a cylinder, the ratio d/h of the diameter d to the height h is preferably from 0.2 to 20. In case the block electrode 5 is a prism having rectangular cross section, the ratio d/h of the longer diagonal d to the height h may be from 0.2 to 20. In case the block electrode 5 is a prism having hexagonal cross section, the ratio d/h of the longest diagonal d among the nine diagonals to the height h may be from 0.2 to 20. In case the block electrode 5 is a prism having octagonal cross section, the ratio d/h of the longest diagonal d among the 20 diagonals to the height h may be from 0.2 to 20.

While there are no limitations on the material used to make the wiring conductor 3 and the external connection terminal 4, as long as the material has electrical conductivity so as to allow current to flow easily, it is preferably made of a metal containing at least one element selected from among Zn, Al, Au, Ag, W, Ti, Fe, Cu, Ni and Mg, because of low electrical resistance.

The solder used to join the planar electrode 4 and the block electrode 5 and the solder used to join the thermoelectric element 2 and the wiring conductor 3 preferably have different melting points. In this case, the process of bonding the planar electrode 4 and the block electrode 5 and the process of bonding the thermoelectric element 2 and the wiring conductor 3 are preferably carried out as separately processes. For example, such a procedure may be employed as the thermoelectric element 2 and the wiring conductor 3 are bonded by using an Au—Sn solder having melting point at 280° C. so as to form a module, then the planar electrode 4 and the block electrode 5 provided on the upper support substrate 1b are bonded by using an Sn—Sb solder having melting point at 230° C. This makes it easy to manufacture the thermoelectric module. The temperature difference between melting temperature of a solder that bonds thermoelectric element and wiring conductor 3 and melting temperature of a solder that bonds external connecting electrode and lead member is preferably, for example, about 50° C.

The block electrode 5 may be coated with a thin layer that contains at least one element selected from a group of Ni, Au, Sn, Pt and Co on the surface thereof, which improves the wettability with solder and achieves a joint having better electrical conductivity and bonding strength.

Thus the thermoelectric module of this embodiment allows wire bonding when mounting in the package with high yield of production. The package for the thermoelectric module of this embodiment has a container 26, connection electrodes (not shown) provided in the container 26 and electrode terminals 29 integrated therewith, where the thermoelectric module 11 is placed on the bottom in the package. The top surface of the block electrode and the electrode terminal are provided preferably at substantially the same height in the thermoelectric module 11. Setting the bonding surface of the block electrode 5 and electrode terminal 29 of the package at substantially the same height enables it to minimize the length of the wire and makes the operation easier since it eliminates the necessity to carry out wire bonding within the narrow package.

While there is no restriction on the material used to make the package 26, such materials as Cu—W and C—C composite that have good heat dissipating characteristic can be preferably used.

### EXAMPLES

Now examples of the present invention will be described.

### Example 1

(Fabrication of Thermoelectric Elements)

First, various N-type and P-type thermoelectric materials were made in the following procedure. Metal powders of Bi, Te, Sb and Se of 99.99% or higher purity, SbI₃ and SbBr₃ powders used as dopant for the N-type thermoelectric element were prepared. The N-type thermoelectric material was made by adjusting the dopant content in a basic composition of Bi₂Te_{2.85}Se_{0.15} so as to control the resistivity. The P-type thermoelectric material was made by changing the value of x from 0.3 to 0.7 in a basic composition of BiₓTe₂₋ₓTe₃ so as to control the resistivity.

(a) Fabrication of Sintered Material

Raw materials were weighed according to the desired composition and put into a crucible made of carbon, that was closed with a lid. The crucible was put into a quartz tube and was, after vacuum substitution, fired at 800° C. in argon atmosphere for 5 hours, to make an alloy.

The alloy was crushed into powder with a stamp mill in a glove box, with the powder being passed through a sieve of 2 mm mesh and crushed again with a small-amplitude vibration mill using balls made of silicon nitride for one to twelve hours. The alloy powder was then reduced by heating at 450° C. in hydrogen gas stream for one hour thereby to obtain fine alloy powder.

The powder was hot-pressed using a carbon dice measuring 20 mm in diameter and 10 mm in thickness, thereby to obtain a sintered material.

A rectangular parallelepiped block measuring 2×3×15 mm was cut from the sintered material so that the longitudinal direction of the block coincided with the direction perpendicular to the pressurizing direction. Seebeck coefficient and resistivity (ρ) of the rectangular parallelepiped block were measured with a Seebeck coefficient measuring instrument (ZEM apparatus manufactured by Sinku Riko, Inc.), and power factor (S²/ρ) was calculated using the measured values.

Rest of the sintered material was sliced into thin plates 0.9 mm in thickness so that the direction of thickness coincided with the pressurizing direction. After applying electrodeless plating of Ni and Au plating to the thin plate, the thin plate was diced to obtain thermoelectric elements measuring 0.65 mm square.

(b) Fabrication of Melt-Formed Material 1: Rod-Shaped Sample Made by Unidirectional Solidification

The material made by unidirectional solidification, as an example of melt-formed material, was fabricated as follows. The alloy powder made by the same method as described above was placed on top of a mold of carbon casting having gaps of square prism shape. This mold is composed of two plates having a plurality of V-shaped grooves. If the two plates are put together so that V-shaped grooves face to each other, square-prism-shaped voids are formed. The square-prism-shaped void is 100 mm long and has a square-shaped cross section of which side is 0.65 mm long. Then the alloy powder was melted at 700° C. in a single crystal growing apparatus (Bridgman method) having vertical core tube made of quartz. After filling the gap with the molten alloy, the alloy was cooled down while moving the mold according to the Bridgman method, so as to grow the crystal at a rate of 2 to 3 mm/hour near the freezing point (600° C.). Thus a long block of thermoelectric crystal grown by unidirectional solidification process was made for the N-type thermoelectric element 2a and the P-type thermoelectric element 2b.

The block of thermoelectric crystal grown by unidirectional solidification process thus obtained was cut to length of 15 mm along the longitudinal direction. Seebeck coefficient and resistivity (ρ) of this rod were measured similarly to the case of the sintered material, and power factor (S²/ρ) was calculated.

Thermoelectric elements were made by using the block of thermoelectric crystal grown by unidirectional solidification process.

First, with the side faces of the rod of the thermoelectric crystal grown by unidirectional solidification process coated with a commercialized plating resist (acrylic resin), the rod was sliced with a dicing saw to a thickness of 0.9 mm, thereby to obtain chips of rectangular parallelepiped shape. The element thus obtained was subjected to electrodeless plating to form Ni plating layer of thickness from 5 to 10 μm, and then Au plating to a thickness of 0.1 μm. The chip was then immersed in an alkaline solution to remove the plating layer deposited on the resist film on the side faces of the chip by means of ultrasound, so as to make the thermoelectric elements having plating layers only on the cut surfaces.

(c) Fabrication of Melt-Formed Material 2: Ingot

As another method of fabricating melt-formed material, crystal was grown into an ingot of φ30 by zone-melt method using an infrared image furnace. The ingot was sliced in a direction perpendicular to the growing direction, to make the thermoelectric elements similarly to the case of the sintered material. Thermoelectric properties of the thermoelectric elements were determined.

(Fabrication of Thermoelectric Module)

The N-type and P-type thermoelectric elements, 23 pieces each, made as described above were arranged by using an array fixture on an alumina ceramics substrate measuring 6×8 mm having copper wiring, and bonded by using an SnSb (95:5) solder paste and heating to a temperature from 250 to 280° C. with a ceramics heater, thereby making thermoelectric module.

The thermoelectric module was placed, via a heat-conductive grease, on a heat sink that was temperature-controlled at 27° C. on the cooling surface, and was supplied with power, while measuring the temperature at the top of the cooling surface with a type K thermocouple having diameter of 0.1 mm. Temperature of the cooling surface was measured while changing the energizing conditions, and the maximum temperature difference was determined when the temperature of the cooling surface showed the largest difference from 27° C.

The cooling surface was heated with a ceramic heater of the same shape as the cooling surface substrate under the energizing conditions under which the maximum temperature difference was obtained, and the output power of the ceramic heater when the temperature of the cooling surface reached 27° C. was taken as the heat absorbing capacity.

Then mean grain size was measured on about 300 grains by line intercept method through SEM observation of a fracture surface of the thermoelectric elements obtained as described above.

The results are shown in Table 1-1 and 1-2.

TABLE 1-1

| | N-type thermoelectric element | | | | | |
|---|---|---|---|---|---|---|
| | Manufacturing | | SbI₃ content | Particle size | Resistivity | Power factor |
| No. | method | Shape | wt % | μm | 10-5 Ωm | 10-3 W/mK2 |
| 1 | Sintering | Ingot | 0.12 | 23 | 0.65 | 4.3 |
| 2 | Sintering | Ingot | 0.12 | 22 | 0.68 | 4.3 |
| 3 | Sintering | Ingot | 0.11 | 20 | 0.70 | 4.3 |
| 4 | Sintering | Ingot | 0.11 | 19 | 0.80 | 4.2 |
| 5 | Sintering | Ingot | 0.1 | 21 | 0.85 | 4.3 |
| 6 | Sintering | Ingot | 0.1 | 25 | 0.90 | 4.2 |
| 7 | Sintering | Ingot | 0.09 | 20 | 0.95 | 4.2 |
| *8 | Sintering | Ingot | 0.09 | 21 | 0.96 | 4.2 |
| *9 | Sintering | Ingot | 0.09 | 20 | 0.97 | 4.2 |
| *10 | Sintering | Ingot | 0.08 | 22 | 1.00 | 4.2 |
| *11 | Sintering | Ingot | 0.08 | 21 | 1.03 | 4.2 |
| *12 | Sintering | Ingot | 0.08 | 22 | 1.04 | 4.2 |
| 13 | Sintering | Ingot | 0.08 | 19 | 1.05 | 4.2 |
| 14 | Sintering | Ingot | 0.07 | 22 | 1.10 | 4.2 |
| 15 | Sintering | Ingot | 0.07 | 22 | 1.14 | 4.1 |
| 16 | Sintering | Ingot | 0.06 | 24 | 1.21 | 4.2 |
| 17 | Sintering | Ingot | 0.06 | 25 | 1.25 | 4.1 |
| 18 | Sintering | Ingot | 0.05 | 25 | 1.30 | 4.1 |
| 19 | Sintering | Ingot | 0.05 | 24 | 1.31 | 4.1 |
| 20 | Sintering | Ingot | 0.05 | 26 | 1.35 | 4.1 |
| 21 | Sintering | Ingot | 0.06 | 26 | 1.25 | 4.0 |
| 22 | Sintering | Ingot | 0.06 | 29 | 1.24 | 3.9 |
| 23 | Sintering | Ingot | 0.06 | 29 | 1.24 | 3.8 |

| | P-type thermoelectric element | | | | |
|---|---|---|---|---|---|
| | Manufacturing | | Particle size | Resistivity | Power factor |
| No. | method | Shape | μm | 10-5 Ωm | 10-3 W/mK2 |
| 1 | Sintering | Ingot | 28 | 1.00 | 4.4 |
| 2 | Sintering | Ingot | 28 | 1.00 | 4.4 |
| 3 | Sintering | Ingot | 28 | 1.00 | 4.4 |
| 4 | Sintering | Ingot | 28 | 1.00 | 4.4 |
| 5 | Sintering | Ingot | 28 | 1.00 | 4.4 |
| 6 | Sintering | Ingot | 28 | 1.00 | 4.4 |
| 7 | Sintering | Ingot | 28 | 1.00 | 4.4 |
| *8 | Sintering | Ingot | 28 | 1.00 | 4.4 |
| *9 | Sintering | Ingot | 28 | 1.00 | 4.4 |
| *10 | Sintering | Ingot | 28 | 1.00 | 4.4 |
| *11 | Sintering | Ingot | 28 | 1.00 | 4.4 |
| *12 | Sintering | Ingot | 28 | 1.00 | 4.4 |
| 13 | Sintering | Ingot | 28 | 1.00 | 4.4 |
| 14 | Sintering | Ingot | 28 | 1.00 | 4.4 |
| 15 | Sintering | Ingot | 28 | 1.00 | 4.4 |
| 16 | Sintering | Ingot | 28 | 1.00 | 4.4 |
| 17 | Sintering | Ingot | 28 | 1.00 | 4.4 |
| 18 | Sintering | Ingot | 28 | 1.00 | 4.4 |
| 19 | Sintering | Ingot | 28 | 1.00 | 4.4 |
| 20 | Sintering | Ingot | 28 | 1.00 | 4.4 |
| 21 | Sintering | Ingot | 28 | 1.00 | 4.4 |
| 22 | Sintering | Ingot | 28 | 1.00 | 4.4 |
| 23 | Sintering | Ingot | 28 | 1.00 | 4.4 |

| | Resistivity ratio | Module characteristic | |
|---|---|---|---|
| | N-type/P-type | Temperature difference | Heat absorbing capacity |
| No. | 10-3 W/mK2 | ° C. | W |
| 1 | 0.65 | 74.3 | 3.03 |
| 2 | 0.68 | 74.7 | 3.03 |
| 3 | 0.70 | 75.1 | 3.03 |
| 4 | 0.80 | 75.2 | 3.01 |
| 5 | 0.85 | 75.3 | 3.03 |
| 6 | 0.90 | 74.9 | 3.03 |
| 7 | 0.95 | 74.7 | 3.03 |
| *8 | 0.96 | 73.7 | 2.98 |
| *9 | 0.97 | 73.6 | 2.99 |
| *10 | 1.00 | 73.5 | 3.01 |
| *11 | 1.03 | 73.3 | 3.03 |
| *12 | 1.04 | 73.2 | 3.03 |
| 13 | 1.05 | 73.7 | 3.15 |
| 14 | 1.10 | 73.7 | 3.18 |
| 15 | 1.14 | 73.7 | 3.22 |
| 16 | 1.21 | 73.8 | 3.28 |
| 17 | 1.25 | 73.7 | 3.23 |
| 18 | 1.30 | 73.7 | 3.18 |
| 19 | 1.31 | 73.7 | 3.10 |
| 20 | 1.35 | 73.7 | 3.10 |
| 21 | 1.25 | 73.7 | 3.20 |
| 22 | 1.24 | 73.8 | 3.17 |
| 23 | 1.24 | 73.7 | 3.11 |

*Beyond the scope of invention

TABLE 1-2

| | N-type thermoelectric element | | | | | |
|---|---|---|---|---|---|---|
| | Manufacturing | | SbI₃ content | Particle size | Resistivity | Power factor |
| No. | method | Shape | wt % | μm | 10-5 Ωm | 10-3 W/mK2 |
| 24 | Sintering | Ingot | 0.06 | 29 | 1.25 | 4.1 |
| 25 | Sintering | Ingot | 0.06 | 29 | 1.25 | 4.1 |
| 26 | Sintering | Ingot | 0.06 | 29 | 1.25 | 4.1 |
| 27 | Melt forming | Ingot | 0.08 | >200 | 1.01 | 4.3 |
| *28 | Melt forming | Ingot | 0.08 | >200 | 1.01 | 4.3 |
| 29 | Melt forming | Ingot | 0.08 | >200 | 1.01 | 4.3 |
| 30 | Melt forming | Rod | 0.06 | — | 1.12 | 4.4 |
| 31 | Melt forming | Rod | 0.06 | — | 1.12 | 4.4 |
| 32 | Melt forming | Rod | 0.06 | — | 1.12 | 4.4 |
| *33 | Melt forming | Rod | 0.06 | — | 1.12 | 4.4 |
| 34 | Melt forming | Rod | 0.06 | — | 1.12 | 4.4 |
| 35 | Melt forming | Rod | 0.06 | — | 1.12 | 4.4 |
| 36 | Melt forming | Rod | 0.06 | — | 1.12 | 4.4 |
| 37 | Melt forming | Rod | 0.06 | — | 1.12 | 4.4 |
| 38 | Melt forming | Rod | 0.06 | — | 1.12 | 4.4 |
| 39 | Melt forming | Rod | 0.06 | — | 1.12 | 4.4 |
| 40 | Melt forming | Rod | 0.06 | — | 1.12 | 4.4 |
| 41 | Melt forming | Rod | 0.06 | — | 1.12 | 4.4 |
| *42 | Melt forming | Rod | 0.06 | — | 1.12 | 4.4 |
| 43 | Melt forming | Rod | 0.06 | — | 1.12 | 4.4 |
| 44 | Melt forming | Rod | 0.06 | — | 1.12 | 4.4 |
| *45 | Melt forming | Rod | 0.06 | — | 1.12 | 4.4 |
| 46 | Melt forming | Rod | 0.06 | — | 1.12 | 4.4 |

| | P-type thermoelectric element | | | | |
|---|---|---|---|---|---|
| | | | Particle size | Resistivity | Power factor |
| No. | Manufacturing method | Shape | μm | 10-5 Ωm | 10-3 W/mK2 |
| 24 | Sintering | Ingot | 28 | 1.00 | 4.0 |
| 25 | Sintering | Ingot | 35 | 1.11 | 3.9 |
| 26 | Sintering | Ingot | 33 | 1.08 | 3.8 |
| 27 | Sintering | Ingot | 31 | 0.85 | 4.4 |
| *28 | Sintering | Ingot | 28 | 1.00 | 4.4 |
| 29 | Sintering | Ingot | 33 | 1.13 | 4.4 |
| 30 | Sintering | Ingot | 28 | 0.95 | 4.4 |
| 31 | Sintering | Ingot | 27 | 1.00 | 4.4 |
| 32 | Sintering | Ingot | 25 | 1.07 | 4.4 |
| *33 | Sintering | Ingot | 28 | 1.11 | 4.4 |
| 34 | Sintering | Ingot | 31 | 1.18 | 4.4 |
| 35 | Sintering | Ingot | 33 | 1.22 | 4.4 |
| 36 | Sintering | Ingot | 25 | 1.27 | 4.4 |
| 37 | Sintering | Ingot | 25 | 1.31 | 4.4 |
| 38 | Sintering | Ingot | 45 | 1.02 | 4.3 |
| 39 | Sintering | Ingot | 70 | 0.98 | 4.4 |
| 40 | Sintering | Ingot | 120 | 0.95 | 4.4 |
| 41 | Melt forming | Ingot | >200 | 0.99 | 4.5 |
| *42 | Melt forming | Ingot | >200 | 1.11 | 4.5 |
| 43 | Melt forming | Ingot | >200 | 1.19 | 4.5 |
| 44 | Melt forming | Rod | — | 1.00 | 4.5 |
| *45 | Melt forming | Rod | — | 1.12 | 4.5 |
| 46 | Melt forming | Rod | — | 1.22 | 4.5 |

| | Resistivity ratio | Module characteristic | |
|---|---|---|---|
| | N-type/P-type | Temperature difference | Heat absorbing capacity |
| No. | 10-3 W/mK2 | ° C. | W |
| 24 | 1.25 | 73.7 | 3.18 |
| 25 | 1.13 | 73.7 | 3.12 |
| 26 | 1.16 | 73.7 | 3.10 |
| 27 | 1.19 | 73.8 | 3.36 |
| *28 | 1.01 | 73.7 | 3.03 |
| 29 | 0.89 | 75.8 | 3.11 |
| 30 | 1.18 | 73.7 | 3.50 |
| 31 | 1.12 | 73.7 | 3.42 |
| 32 | 1.05 | 73.8 | 3.38 |
| *33 | 1.01 | 73.7 | 3.03 |
| 34 | 0.95 | 74.8 | 3.05 |
| 35 | 0.92 | 75.3 | 3.05 |
| 36 | 0.88 | 75.9 | 3.05 |
| 37 | 0.85 | 76.2 | 3.05 |
| 38 | 1.10 | 74.0 | 3.40 |
| 39 | 1.14 | 73.8 | 3.37 |
| 40 | 1.18 | 73.8 | 3.36 |
| 41 | 1.13 | 73.7 | 3.38 |
| *42 | 1.01 | 73.7 | 3.03 |
| 43 | 0.94 | 75.2 | 3.06 |
| 44 | 1.12 | 73.8 | 3.41 |
| *45 | 1.00 | 73.7 | 3.03 |
| 46 | 0.92 | 75.2 | 3.06 |

*Beyond the scope of invention

(a) Influence of Resistivity of N-Type Thermoelectric Element and P-Type Thermoelectric Element

As will be clear from Table 1, maximum temperature difference was in a range from 73.2 to 73.8° C. and heat absorbing capacity was in a range from 3.01 to 3.06 W in comparative examples Nos. 8 through 11, 28, 33, 42 and 45 where the N-type thermoelectric element 2a and the P-type thermoelectric element 2b had substantially the same resistivity. The examples Nos. 1 through 7, 13 through 27, 29 through 32, 34 through 41, 43, 44 and 46 where the N-type thermoelectric element 2a and the P-type thermoelectric element 2b had different values of resistivity, in contrast, showed maximum temperature difference of 74.3° C. or higher and heat absorbing capacity of 3.10 W or more, indicating that the thermoelectric module had better performance either in maximum temperature difference or heat absorbing capacity.

Specifically, in the examples Nos. 1 through 7, 29, 34 through 37, 43 and 46 where the N-type thermoelectric element had resistivity substantially lower that that of the P-type thermoelectric element, the heat absorbing capacity was not substantially different from that of the comparative example, but maximum temperature difference was 74.3° C. or higher, significantly greater than in the comparative example. When the samples Nos. 1 through 10 having the thermoelectric elements of the same manufacturing method and shape are compared, it can be seen that still larger maximum temperature difference was obtained in a range of ratios of resistivity of the N-type thermoelectric element to that of the P-type thermoelectric element from 0.7 to 0.95.

In the examples Nos. 13 through 27, 30 through 32, 38 through 41 and 44 where the N-type thermoelectric element had resistivity substantially lower that that of the P-type thermoelectric element, the maximum temperature difference was not significantly different from that of the comparative example, but heat absorbing capacity was 3.10 W or more, significantly greater than in the comparative example. When the samples Nos. 11 through 20 having the thermoelectric elements of the same manufacturing method and shape are compared, it can be seen that still larger heat absorbing capacity was obtained in a range of ratios of resistivity of the N-type thermoelectric element to that of the P-type thermoelectric element from 1.05 to 1.30.

(b) Influence of the Manufacturing Method of N-Type Thermoelectric Element

Samples Nos. 1 through 26 comprised the N-type thermoelectric element and the P-type thermoelectric element both made of sintered material, while samples Nos. 27 through 29 comprised the N-type thermoelectric element made of melt-formed material and the P-type thermoelectric element made of sintered material. Thus the samples Nos. 1 through 26 and the samples Nos. 27 through 29 differed from each other with regards to whether the N-type thermoelectric element was made of sintered material or melt-formed material. Among these samples, comparison is made between No. 6 and No. 29 and between No. 16 and No. 27 which have similar values of resistivity, and samples No. 29 and No. 27 having the N-type thermoelectric elements made of melt-formed material showed better characteristics in the respective comparisons. Thus it can be seen that better characteristic of the module can be obtained by using the N-type thermoelectric element made of sintered material, rather than melt-formed material.

While the samples Nos. 27 through 29 comprised N-type thermoelectric elements made from melt-formed material, the samples Nos. 30 through 40 comprised N-type thermoelectric elements made from a rod formed by unidirectional solidification process. Among these samples, samples No. 27 and No. 30 were compared, and it was found that No. 27 showed heat absorbing capacity of 3.26 W while the No. 30 showed heat absorbing capacity of 3.50 W. This result shows that better characteristic can be obtained by forming the N-type thermoelectric element by unidirectional solidification process.

(c) Influence of Power Factor

Samples Nos. 15 and 17 through 20 showed that the N-type thermoelectric element had power factor of 4.1×10⁻³ W/mK², and the P-type thermoelectric element had power factor of 4.4×10⁻³ W/mK².

Samples Nos. 21 through 23, in contrast, showed that the P-type thermoelectric element had power factor of 4.4×10⁻³ W/mK², the same as the above, but the N-type thermoelectric element had power factor of 4.0×10⁻³ W/mK², lower than the above. When the heat absorbing capacity of the samples Nos. 21 through 23 was compared to that of the samples No. 17 that had the ratio of resistivity of similar value, heat absorbing capacity of No. 17 was 3.23 W but the samples Nos. 21 through 23 showed lower values of 3.11 to 3.20 W. Among the samples Nos. 21 through 23, a sample having the N-type thermoelectric element of lower power factor showed lower value of heat absorbing capacity.

Samples Nos. 24 through 26 showed that the N-type thermoelectric element had power factor of 4.1×10⁻³ W/mK², the same as that of samples Nos. 15 and 17 through 20, although the P-type thermoelectric element had power factor of 4.0×10⁻³ W/mK², lower than the above. When the heat absorbing capacity of the samples Nos. 24 through 26 was compared to that of the samples Nos. 15 and 17 that had the ratio of resistivity of similar value, heat absorbing capacity was 3.22 W in No. 15 and 3.23 W in No. 17, but the samples Nos. 24 through 26 showed lower values of 3.10 to 3.18 W. Among the samples Nos. 24 through 26, a sample having the P-type thermoelectric element of lower power factor showed lower value of heat absorbing capacity.

From the results described above, it can be seen that the N-type thermoelectric element and the P-type thermoelectric element preferably have power factor of 4.0×10⁻³ W/mK² or higher.

(d) Influence of Particle Size

In samples No. 38, 39 and 40, the P-type thermoelectric element was made of sintered material consisting of progressively larger particles measuring 45, 70 and 120 μm, respectively, with other conditions substantially the same. These samples showed heat absorbing capacity of 3.40 W, 3.37 W and 3.36 W, respectively. The heat absorbing capacity decreases as the particle size of the sintered material increases beyond 50 μm.

### Example 2

The thermoelectric elements 2 made of sintered Bi₂Te_{2.85}Se_{0.15} having rectangular prism shape measuring 0.6 mm, 0.6 mm and 1 mm was prepared. The support substrate 1 made of alumina measuring 6 mm and 8 mm was prepared.

The wiring conductor 3 made of Cu was formed on the support substrate 1 by plating-etching process, with the surface further coated with an Au layer 7.

Paste of solder 6 such as Au—Sn was printed on the wiring conductor 3a of the lower support substrate 1a, and the thermoelectric elements 2 were placed thereon and secured by heating the lower support substrate 1a on the opposite side. The thermoelectric elements 2 consisted of the same numbers of the N-type thermoelectric element 2a and the P-type thermoelectric elements 2b. The thermoelectric module 11 was made by securing the other upper support substrate 1b and the thermoelectric elements 2.

The lead wire 5 was connected by locally heating with soft beam or the like while feeding the solder 10 on the wiring conductor 3 of the thermoelectric module 11.

Parallelism of the wiring conductor was determined by measuring the height of the wiring conductor at four corners with a height gage and calculating the difference between the maximum and minimum height. Flatness was determined by measuring the height of the wiring conductor at four corners and the center with a height gage and calculating the difference between the maximum and minimum height.

Bonding strength between the coating layer and the solder was determined by pulling a wire bonded with solder (Sn—Sb) through a hole of 1 mm square formed in a tape and measuring the peel-off strength.

A dummy weight of 1 g was bonded onto the cooling surface of the thermoelectric module 11, and conducted shock test in accordance to MIL-STD-883, METHOD 2002, CONDITION B. Energization cycle test was conducted by reversing the direction of current flow every 15 seconds in an oil maintained at 30° C. Resistance was measured before and after each test by AC four-probe analysis method. It was determined that the sample passed the test when the change in resistance (ΔR) was 5% or less, and failed when ΔR was over 5%.

TABLE 2

| | | Angle A between | | | | | | | | |
|---|---|---|---|---|---|---|---|---|---|---|
| | Cross | element bonding | | | | | | Coating layer | | |
| | section | surface and | | | Wiring conductor | | | | | Peel-off |
| Sample | of wiring | adjoining surface | Parallelism | Fatness | Material | Heat | Resistivity | | Resistivity | strength |
| No. | conductor | (°) | (mm) | (mm) | (W/m · K) | conductivity | (×10⁻⁸ Ω · m) | Material | (×10⁻⁸ Ω · m) | (kg/mm²) |
| 1 | Trapezoid | 80 | 0.02 | 0.02 | Cu | 360 | 1.55 | Au | 2.04 | 1.7 |
| 2 | Trapezoid | 70 | 0.02 | 0.02 | Cu | 360 | 1.55 | Au | 2.04 | 1.7 |
| 3 | Trapezoid | 60 | 0.02 | 0.02 | Cu | 360 | 1.55 | Au | 2.04 | 1.7 |
| 4 | Trapezoid | 50 | 0.02 | 0.02 | Cu | 360 | 1.55 | Au | 2.04 | 1.7 |
| 5 | Trapezoid | 40 | 0.02 | 0.02 | Cu | 360 | 1.55 | Au | 2.04 | 1.7 |
| 6 | Trapezoid | 80 | 0.08 | 0.08 | Cu | 360 | 1.55 | Au | 2.04 | 1.7 |
| 7 | Trapezoid | 80 | 0.15 | 0.15 | Cu | 360 | 1.55 | Au | 2.04 | 1.7 |
| 8 | Trapezoid | 80 | 0.05 | 0.15 | Cu | 360 | 1.55 | Au | 2.04 | 1.7 |
| 9 | Trapezoid | 80 | 0.02 | 0.02 | Ag | 420 | 1.50 | Au | 2.04 | 1.9 |
| 10 | Trapezoid | 80 | 0.02 | 0.02 | Al | 230 | 2.50 | Au | 2.04 | 1.5 |
| 11 | Trapezoid | 80 | 0.02 | 0.02 | Fe | 76 | 8.71 | Au | 2.04 | 1.4 |
| 12 | Trapezoid | 80 | 0.02 | 0.02 | Ni | 92 | 6.58 | Au | 2.04 | 1.6 |
| 13 | Trapezoid | 80 | 0.02 | 0.02 | Pt | 71 | 9.81 | Au | 2.04 | 1.8 |
| 14 | Trapezoid | 80 | 0.02 | 0.02 | Pd | 71 | 9.77 | Au | 2.04 | 1.5 |
| 15 | Trapezoid | 80 | 0.02 | 0.02 | Pb | 35 | 19.30 | Au | 2.04 | 1.2 |
| 16 | Trapezoid | 80 | 0.02 | 0.02 | Cu | 360 | 1.55 | Sn | 10.1 | 1.5 |
| 17 | Trapezoid | 80 | 0.02 | 0.02 | Cu | 360 | 1.55 | Ni | 6.58 | 1.1 |
| 18 | Trapezoid | 80 | 0.02 | 0.02 | Cu | 360 | 1.55 | Cr | 13 | 0.9 |
| 19 | Trapezoid | 80 | 0.02 | 0.02 | Cu | 360 | 1.55 | Au | 2.04 | 1.7 |

| | | | | Shock test | | Energization cycle test | |
|---|---|---|---|---|---|---|---|
| | | | | | No. of NG/subjects | | No. of NG/subjects |
| Sample | Wiring conductor | Thermoelectric element | | | of reliability | | of reliability |
| No. | forming method | P-type | N-type | Max. ΔR | test | Max. ΔR | test |
| 1 | Plating | Bi_{0.5}Sb_{1.5}Te₂ | Bi₂Te_{2.85}Se_{0.15} | 1.5 | 0/10 | 1.0 | 0/10 |
| 2 | Plating | Bi_{0.5}Sb_{1.5}Te₂ | Bi₂Te_{2.85}Se_{0.15} | 1.7 | 0/10 | 1.2 | 0/10 |
| 3 | Plating | Bi_{0.5}Sb_{1.5}Te₂ | Bi₂Te_{2.85}Se_{0.15} | 1.8 | 0/10 | 1.2 | 0/10 |
| 4 | Plating | Bi_{0.5}Sb_{1.5}Te₂ | Bi₂Te_{2.85}Se_{0.15} | 2.1 | 0/10 | 1.7 | 0/10 |
| 5 | Plating | Bi_{0.5}Sb_{1.5}Te₂ | Bi₂Te_{2.85}Se_{0.15} | 3.9 | 0/10 | 3.5 | 0/10 |
| 6 | Plating | Bi_{0.5}Sb_{1.5}Te₂ | Bi₂Te_{2.85}Se_{0.15} | 2.7 | 0/10 | 2.2 | 0/10 |
| 7 | Plating | Bi_{0.5}Sb_{1.5}Te₂ | Bi₂Te_{2.85}Se_{0.15} | 4.1 | 0/10 | 3.8 | 0/10 |
| 8 | Plating | Bi_{0.5}Sb_{1.5}Te₂ | Bi₂Te_{2.85}Se_{0.15} | 3.8 | 0/10 | 3.5 | 0/10 |
| 9 | Plating | Bi_{0.5}Sb_{1.5}Te₂ | Bi₂Te_{2.85}Se_{0.15} | 1.7 | 0/10 | 1.1 | 0/10 |
| 10 | Plating | Bi_{0.5}Sb_{1.5}Te₂ | Bi₂Te_{2.85}Se_{0.15} | 1.9 | 0/10 | 1.4 | 0/10 |
| 11 | Plating | Bi_{0.5}Sb_{1.5}Te₂ | Bi₂Te_{2.85}Se_{0.15} | 1.7 | 0/10 | 1.4 | 0/10 |
| 12 | Plating | Bi_{0.5}Sb_{1.5}Te₂ | Bi₂Te_{2.85}Se_{0.15} | 1.7 | 0/10 | 1.2 | 0/10 |
| 13 | Plating | Bi_{0.5}Sb_{1.5}Te₂ | Bi₂Te_{2.85}Se_{0.15} | 1.9 | 0/10 | 1.3 | 0/10 |
| 14 | Plating | Bi_{0.5}Sb_{1.5}Te₂ | Bi₂Te_{2.85}Se_{0.15} | 1.8 | 0/10 | 1.2 | 0/10 |
| 15 | Plating | Bi_{0.5}Sb_{1.5}Te₂ | Bi₂Te_{2.85}Se_{0.15} | 2.0 | 0/10 | 1.8 | 0/10 |
| 16 | Plating | Bi_{0.5}Sb_{1.5}Te₂ | Bi₂Te_{2.85}Se_{0.15} | 2.2 | 0/10 | 1.8 | 0/10 |
| 17 | Plating | Bi_{0.5}Sb_{1.5}Te₂ | Bi₂Te_{2.85}Se_{0.15} | 2.4 | 0/10 | 1.9 | 0/10 |
| 18 | Plating | Bi_{0.5}Sb_{1.5}Te₂ | Bi₂Te_{2.85}Se_{0.15} | 2.8 | 0/10 | 2.2 | 0/10 |
| 19 | Metallization | Bi_{0.5}Sb_{1.5}Te₂ | Bi₂Te_{2.85}Se_{0.15} | 1.8 | 0/10 | 1.3 | 0/10 |

| | | Angle A between | | | | | | | | |
|---|---|---|---|---|---|---|---|---|---|---|
| | | element bonding | | | | | | Coating layer | | |
| | Cross section | surface and | | | Wiring conductor | | | | | Peel-off |
| Sample | of wiring | adjoining surface | Parallelism | Fatness | Material | Heat | Resistivity | | Resistivity | strength |
| No. | conductor | (°) | (mm) | (mm) | (W/m · K) | conductivity | (×10⁻⁸ Ω · m) | Material | (×10⁻⁸ Ω · m) | (kg/mm²) |
| 20 | Trapezoid | 80 | 0.02 | 0.02 | Cu | 360 | 1.55 | Au | 2.04 | 1.7 |
| 21 | Trapezoid | 80 | 0.02 | 0.02 | Cu | 360 | 1.55 | Au | 2.04 | 1.7 |
| 22 | Trapezoid | 80 | 0.02 | 0.02 | W | 202 | 4.89 | Au | 2.04 | 1.4 |
| 23 | Rectangle | 90 | 0.02 | 0.02 | Cu | 360 | 1.55 | Au | 2.04 | 1.7 |
| *24 | Trapezoid | 120 | 0.02 | 0.02 | Cu | 360 | 1.55 | Au | 2.04 | 1.7 |
| | (Upper side < | | | | | | | | | |
| | Lower side) | | | | | | | | | |
| *25 | D-shaped | 160 | 0.10 | 0.10 | Cu | 360 | 1.55 | Au | 2.04 | 1.7 |
| | section | | | | | | | | | |
| *26 | Hexagon | 135 | 0.10 | 0.10 | Cu | 360 | 1.55 | Au | 2.04 | 1.7 |
| *27 | Quadrangle | 100 | 0.10 | 0.10 | Cu | 360 | 1.55 | Au | 2.04 | 1.7 |
| | (No parallel | | | | | | | | | |
| | surfaces) | | | | | | | | | |
| *28 | Quadrangle | 110 | 0.10 | 0.10 | Cu | 360 | 1.55 | Au | 2.04 | 1.7 |
| | (No parallel | | | | | | | | | |
| | surfaces) | | | | | | | | | |
| 29 | Trapezoid | 80 | 0.02 | 0.02 | Cu | 360 | 1.55 | Au | 2.04 | 1.7 |
| 30 | Rectangle | 90 | 0.02 | 0.02 | Cu | 360 | 1.55 | Au | 2.04 | 1.7 |
| 31 | Trapezoid | 80 | 0.02 | 0.02 | Cu | 360 | 1.55 | Au | 2.04 | 1.7 |
| 32 | Rectangle | 90 | 0.02 | 0.02 | Cu | 360 | 1.55 | Au | 2.04 | 1.7 |

| | | | | Shock test | | Energization cycle test | |
|---|---|---|---|---|---|---|---|
| | | | | | No. | | No. |
| Sample | Wiring conductor forming | Thermoelectric element | | | of NG/subjects of | | of NG/subjects of |
| No. | method | P-type | N-type | Max. ΔR | reliability test | Max. ΔR | reliability test |
| 20 | DBC | Bi_{0.5}Sb_{1.5}Te₂ | Bi₂Te_{2.85}Se_{0.15} | 1.6 | 0/10 | 1.3 | 0/10 |
| 21 | Chip bonding | Bi_{0.5}Sb_{1.5}Te₂ | Bi₂Te_{2.85}Se_{0.15} | 1.8 | 0/10 | 1.2 | 0/10 |
| 22 | Simultaneous sintering | Bi_{0.5}Sb_{1.5}Te₂ | Bi₂Te_{2.85}Se_{0.15} | 2.2 | 0/10 | 1.7 | 0/10 |
| 23 | Plating | Bi_{0.5}Sb_{1.5}Te₂ | Bi₂Te_{2.85}Se_{0.15} | 1.6 | 0/10 | 1.2 | 0/10 |
| *24 | Plating | Bi_{0.5}Sb_{1.5}Te₂ | Bi₂Te_{2.85}Se_{0.15} | 10.2 | 2/10 | 8.1 | 1/10 |
| *25 | Plating | Bi_{0.5}Sb_{1.5}Te₂ | Bi₂Te_{2.85}Se_{0.15} | 11.2 | 2/10 | 8.3 | 1/10 |
| *26 | Plating | Bi_{0.5}Sb_{1.5}Te₂ | Bi₂Te_{2.85}Se_{0.15} | 10.6 | 2/10 | 9.2 | 1/10 |
| *27 | Plating | Bi_{0.5}Sb_{1.5}Te₂ | Bi₂Te_{2.85}Se_{0.15} | 5.7 | 1/10 | 5.1 | 1/10 |
| *28 | Plating | Bi_{0.5}Sb_{1.5}Te₂ | Bi₂Te_{2.85}Se_{0.15} | 16.4 | 3/10 | 10.4 | 2/10 |
| 29 | Plating | Bi_{0.4}Sb_{1.6}Te₂ | Bi₂Te_{2.85}Se_{0.15} | 1.5 | 0/10 | 1.2 | 0/10 |
| 30 | Plating | Bi_{0.4}Sb_{1.6}Te₂ | Bi₂Te_{2.85}Se_{0.15} | 1.8 | 0/10 | 1.3 | 0/10 |
| 31 | Plating | Bi_{0.5}Sb_{1.5}Te₂ | Bi₂Te_{2.9}Se_{0.1} | 1.2 | 0/10 | 0.9 | 0/10 |
| 32 | Plating | Bi_{0.5}Sb_{1.5}Te₂ | Bi₂Te_{2.9}Se_{0.1} | 1.5 | 0/10 | 1.1 | 0/10 |

*Beyond the scope of invention.

Samples Nos. 1 through 23 and 29 through 32 having the wiring conductor of such a cross section as rectangular, or a trapezoid with the upper side longer than the lower side showed change in resistance of 5% or less before and after the shock test and the energization cycle test, showing satisfactory performance. Among these, samples Nos. 1 through 4, 6, 29 through 23 and 29 through 32 where the angle between the thermoelectric element bonding surface and the adjacent surface of the wiring conductor was in a range from 45 to 90° and the parallelism and flatness were within 0.1 mm were excellent in all evaluations, with the change in resistance 3% or less, that was within the tolerable error of measurement.

The samples of comparative example Nos. 24 through 26 had wiring conductor of such cross sections as trapezoid with the upper side shorter than the lower side, D-shape and hexagon. Failure in reliability test occulted in all of these, showing clearly lower performance than the samples Nos. 1 through 23 and 29 through 32. The sample of comparative example No. 27 having wiring conductor of rectangular cross section showed poor flatness of 0.1 mm of the wiring conductor surface, with reliability clearly lower than the samples Nos. 1 through 23 and 29 through 32. The sample of comparative example No. 28 having wiring conductor of rectangular cross section showed poor parallelism of 0.1 mm of the wiring conductor surface, with reliability clearly lower than the samples Nos. 1 through 23 and 29 through 32.

### Example 3

The thermoelectric module was made similarly to the second example, except for changing the composition of the solder used to connect the lead wire.

The thermoelectric module was left to stand in high temperature atmosphere of 170° C., and the change in resistance (ΔR) was measured by AC four-probe analysis method after 100 hours. Sample with ΔR over 5% was graded as x and that of 5% or less was graded as ◯.

TABLE 3

| | Solder composition for lead | | | | | | | | | |
|---|---|---|---|---|---|---|---|---|---|---|
| | wire | | | | | Void ratio | | | | |
| Sample | Sn | Other component | | | | of element | Thermoelectric element | | | |
| No. | (Weight %) | (Weight %) | | | | (%) | P-type | N-type | ΔR (%) | Judgment |
| 1 | 20 | Au | 80 | | | 2 | Bi_{0.5}Sb_{1.5}Te₂ | Bi₂Te_{2.85}Se_{0.15} | 0.2 | A |
| 2 | 12 | Au | 88 | | | 2 | Bi_{0.5}Sb_{1.5}Te₂ | Bi₂Te_{2.85}Se_{0.15} | 0.3 | A |
| 3 | 30 | Au | 70 | | | 2 | Bi_{0.5}Sb_{1.5}Te₂ | Bi₂Te_{2.85}Se_{0.15} | 1 | A |
| 4 | 40 | Au | 60 | | | 2 | Bi_{0.5}Sb_{1.5}Te₂ | Bi₂Te_{2.85}Se_{0.15} | 3 | A |
| *5 | 5 | Au | 95 | | | 2 | Bi_{0.5}Sb_{1.5}Te₂ | Bi₂Te_{2.85}Se_{0.15} | Unable | C |
| | | | | | | | | | to bond | |
| *6 | 50 | Au | 50 | | | 2 | Bi_{0.5}Sb_{1.5}Te₂ | Bi₂Te_{2.85}Se_{0.15} | 20 | C |
| *7 | 95 | Sb | 5 | | | 2 | Bi_{0.5}Sb_{1.5}Te₂ | Bi₂Te_{2.85}Se_{0.15} | ∞ | C |
| *8 | 60 | Pd | 40 | | | 2 | Bi_{0.5}Sb_{1.5}Te₂ | Bi₂Te_{2.85}Se_{0.15} | ∞ | C |
| *9 | 96.5 | Ag | 3 | Cu | 0.5 | 2 | Bi_{0.5}Sb_{1.5}Te₂ | Bi₂Te_{2.85}Se_{0.15} | ∞ | C |
| 10 | 20 | Au | 80 | | | 1 | Bi_{0.5}Sb_{1.5}Te₂ | Bi₂Te_{2.85}Se_{0.15} | 0.2 | A |
| 11 | 20 | Au | 80 | | | 5 | Bi_{0.5}Sb_{1.5}Te₂ | Bi₂Te_{2.85}Se_{0.15} | 1 | A |
| 12 | 20 | Au | 80 | | | 10 | Bi_{0.5}Sb_{1.5}Te₂ | Bi₂Te_{2.85}Se_{0.15} | 3 | A |
| 13 | 20 | Au | 80 | | | 15 | Bi_{0.5}Sb_{1.5}Te₂ | Bi₂Te_{2.85}Se_{0.15} | 4 | B |
| 14 | 20 | Au | 80 | | | 2 | Bi_{0.5}Sb_{1.5}Te₂ | Bi₂Te_{2.85}Se_{0.15} | 0.1 | A |
| 15 | 20 | Au | 80 | | | 2 | Bi_{0.5}Sb_{1.5}Te₂ | Bi₂Te_{2.9}Se_{0.1} | 0.2 | A |
| 16 | 20 | Au | 80 | | | 2 | Bi_{0.5}Sb_{1.5}Te₂ | Bi₂Te_{2.9}Se_{0.1} | 0.3 | A |

*Beyond the scope of invention.

Samples Nos. 1 through 4 and 10 through 16 where Sn content was in a range from 12% to 40% by weight showed satisfactory values of resistance change within 5%. Among these, samples Nos. 1 through 4, 10 through 12 and 14 through 16 where void ratio of the thermoelectric element was 10% or less were excellent in all evaluations, with the change in resistance being 3% or less, that was within the tolerable error of measurement.

Samples Nos. 5 through 9 where Sn content was less than 12% or more than 40% by weight showed high resistance or complete wire breakage after the test, and were clearly inferior to other samples.

Among the samples where Sn content was in a range from 12% to 40% by weight, sample No. 13 having void ratio higher than 10% passed the test but showed larger value of ΔR than the samples Nos. 10 through 12 where void ratio was 10% or less. Thus it is desirable that void ratio of the solder 10 is not higher than 10%.

### Example 4

The thermoelectric module was made similarly to the second example, except for changing the soldering conditions for connecting the lead wire.

Peel-off strength of the lead member 5 of the thermoelectric module 11 was measured by pulling it in such a direction as the lead member was bent at right angles. Yield of production in mounting in the package was measured.

TABLE 4

| | Thickness of | Ratio of diffusion | Interface | Denseness | | |
|---|---|---|---|---|---|---|
| Sample | diffusion layer | layer to bonding | configuration of | Void ratio of | Void ratio of non- | Power supply |
| No. | (μm) | surface area (%) | diffusion layer | diffusion layer (%) | diffusion layer (%) | line |
| *1 | 0 | 0 | — | — | 30 | Lead wire |
| 2 | 0.1 | 70 | Wavy | 5 | 20 | Lead wire |
| 3 | 0.3 | 70 | Wavy | 5 | 20 | Lead wire |
| 4 | 0.5 | 70 | Wavy | 5 | 25 | Lead wire |
| 5 | 1 | 70 | Wavy | 5 | 20 | Lead wire |
| 6 | 1.5 | 80 | Wavy | 5 | 25 | Lead wire |
| 7 | 2 | 95 | Wavy | 5 | 20 | Lead wire |
| *8 | 0.3 | 10 | Wavy | 5 | 25 | Lead wire |
| 9 | 0.5 | 20 | Wavy | 10 | 30 | Lead wire |
| 10 | 0.5 | 50 | Wavy | 5 | 20 | Lead wire |
| 11 | 0.5 | 90 | Wavy | 5 | 30 | Lead wire |
| 12 | 0.2 | 50 | Wavy | 10 | 30 | Lead wire |
| 13 | 0.4 | 50 | Wavy | 5 | 20 | Lead wire |
| 14 | 0.5 | 50 | Wavy | 5 | 25 | Lead wire |
| 15 | 1 | 50 | Wavy | 5 | 20 | Lead wire |
| 16 | 0.5 | 70 | Flat | 5 | 25 | Lead wire |
| 17 | 0.5 | 70 | Wavy | 5 | 25 | Lead wire |
| 18 | 0.5 | 70 | Wavy | 10 | 30 | Lead wire |
| 19 | 0.5 | 70 | Wavy | 5 | 20 | Lead wire |
| 20 | 0.5 | 70 | Wavy | 10 | 30 | Lead wire |
| 21 | 0.5 | 70 | Wavy | 5 | 20 | Cylinder |
| 22 | 0.5 | 70 | Wavy | 5 | 25 | Prism |
| 23 | 0.5 | 70 | Wavy | 20 | 20 | Lead wire |
| 24 | 0.5 | 70 | Wavy | 15 | 20 | Lead wire |
| 25 | 0.5 | 70 | Wavy | 10 | 20 | Lead wire |

| | Solder | | | | | | |
|---|---|---|---|---|---|---|---|
| Sample | | Melting Point | Bonding temperature | | Peel-off | Short- | Yield of |
| No. | Composition | (° C.) (=A) | (° C.) (=B) | B/Ax100 (%) | strength (N) | circuiting | mounting (%) |
| *1 | Au-Sn | 280 | 280 | 100 | 0.5 | B | 90 |
| 2 | Au-Sn | 280 | 288 | 103 | 2.0 | B | 100 |
| 3 | Au-Sn | 280 | 295 | 105 | 7.0 | B | 100 |
| 4 | Au-Sn | 280 | 300 | 107 | 12.0 | B | 100 |
| 5 | Au-Sn | 280 | 310 | 111 | 15.0 | B | 100 |
| 6 | Au-Sn | 281 | 340 | 121 | 16.0 | B | 100 |
| 7 | Au-Sn | 281 | 370 | 132 | 16.0 | □ | 100 |
| *8 | Au-Sn | 280 | 285 | 102 | 1.0 | B | 90 |
| 9 | Au-Sn | 280 | 300 | 107 | 3.0 | B | 100 |
| 10 | Au-Sn | 280 | 300 | 107 | 8.0 | B | 100 |
| 11 | Au-Sn | 280 | 300 | 107 | 15.0 | B | 100 |
| 12 | Au-Sn | 280 | 290 | 104 | 2.0 | B | 100 |
| 13 | Au-Sn | 280 | 295 | 105 | 5.0 | B | 100 |
| 14 | Au-Sn | 280 | 300 | 107 | 10.0 | B | 100 |
| 15 | Au-Sn | 280 | 320 | 134 | 13.0 | B | 100 |
| 16 | Au-Sn | 280 | 290 | 104 | 8.0 | B | 100 |
| 17 | Au-Sn | 280 | 310 | 111 | 12.0 | B | 100 |
| 18 | Sn-Sb | 240 | 260 | 108 | 13.0 | B | 100 |
| 19 | Sn-Pb | 180 | 195 | 108 | 15.0 | B | 100 |
| 20 | Sn-Ag-Cu | 220 | 235 | 107 | 13.0 | B | 100 |
| 21 | Au-Sn | 280 | 300 | 107 | 12.0 | B | 100 |
| 22 | Au-Sn | 280 | 300 | 107 | 12.0 | B | 100 |
| 23 | Au-Sn | 280 | 300 | 107 | 10.0 | B | 100 |
| 24 | Au-Sn | 280 | 300 | 107 | 11.0 | B | 100 |
| 25 | Au-Sn | 280 | 300 | 107 | 12.0 | B | 100 |

Samples Nos. 2 through 7 and 9 through 20 where the ratio of area of the diffusion layer to the bonding surface was 20% or larger and the diffusion layer was 0.1 μm or thicker showed satisfactory results with the peel-off strength being 2N or higher and yield of mounting being 100%. The sample No. 1 where diffusion layer was not formed and the comparative example where the ratio of area of the diffusion layer to the bonding surface was as low as 10%, in contrast, showed low peel-off strength with failure in the mounting test, indicating clearly inferior performance than other samples.

Now the tests results of the individual samples will be described below.

Short-circuiting occurred due to sagging of the solder caused by excessive heating of the solder in some of sample No. 7.

In sample No. 16, there was no anchoring effect and therefore peel-off strength decreased somewhat since the surface of the diffusion layer was flat, although there was no practical problem. When sample No. 16 is compared with sample No. 4 that has the same thickness of the diffusion layer and the same contact area ratio as those of sample No. 4, peel-off strength is 8N in No. 16 and 12N in No. 4. Thus it can be seen that forming the interface of the diffusion layer in wavy shape greatly improves the bonding strength between the solder and the lead wire.

In samples Nos. 21 and 22, block electrode having a shape of cylinder or prism is bonded instead of the lead wire. In these examples, too, high peel-off strength and high yield of mounting are achieved by forming the diffusion layer having thickness of 0.5 m and area of 70% that of the bonding area. Short-circuiting occurred in both soldered joint and wire-bonded joint in some of samples Nos. 21 and 22.

In samples Nos. 23 through 25, it can be seen that peel-off strength increases as the void ratio of the diffusion layer decreases. These results show that smaller void ratio of diffusion layer is preferable. The proportion of the void ratio of diffusion layer Vd to that of non-diffusion layer Vn, i.e. Vd/Vn is preferably less than 1, more preferably not more than 0.8, further more preferably not more than 0.5.

While these properties can be controlled by means of the melting temperature of the solder, they may also be controlled by means of the temperature raising rate, soldering atmosphere, heat sink or other factors.

### Example 5

The thermoelectric elements made of sintered Bi₂Te_{2.85}Se_{0.15} having rectangular prism shape measuring 0.6 mm, 0.6 mm and 1 mm was prepared. The upper and lower support substrates made of alumina measuring 6 mm and 8 mm was prepared.

Paste of solder 1 such as Au—Sn was printed on the wiring conductor 3a of the lower support substrate, and the thermoelectric elements were placed thereon and secured by heating the insulating substrate on the opposite side. The thermoelectric elements consisted of the same numbers of the N-type thermoelectric element and the P-type thermoelectric elements. The thermoelectric module was made by securing the other insulating substrate and the thermoelectric elements. Melting temperature of the solder 1 is shown in Table 5.

In samples Nos. 3 through 51, the thermoelectric module having the structure shown in FIGS. 7A and 7B was made as follows. Paste of solder 2 such as Sn—Sb was printed on the upper support substrate of the thermoelectric module, and the cylindrical block electrodes were placed thereon and secured by heating the lower support substrate. Melting temperature of the solder and configuration of the block electrode are shown in Table 5. In samples Nos. 1 and 2, the thermoelectric modules of the structures described in Japanese Patent Publication No. 3082170 and Japanese Unexamined Patent Publication (Kokai) No. 11-54806 were made without providing block electrode. Specifically, in sample No. 1, #2 made of NiAu was formed on the lower support substrate 1a to make the wire bonding pad. In sample No. 2, after forming via electrode in the upper support substrate, #2 made of NiAu was formed on the upper surface of the upper support substrate to make the wire bonding pad.

The thermoelectric module made as described above was mounted in a package and tested for evaluation as follows.

Yield was determined by measuring the change in resistance (ΔR) between before and after mounting in the package by four-probe analysis method, and rating as B when ΔR was over 5%, and A when ΔR was within 5%.

Workability was determined by measuring the time required in wiring, and was rated as B when wiring of one line took 20 seconds or more.

Power consumption for maintaining the temperature of the LD constant at 25° C. was measured.

Energization cycle test was conducted to evaluate the reliability. After repeating an energization cycle of flowing current (ON) for 1.5 minutes and shut off the current keeping the OFF state for 4.5 minutes for 5000 cycles, appearance was checked and the change in resistance (ΔR) was measured by four-probe analysis method. 22 pieces from each sample No. were subjected to this test and the sample was evaluated as B if at least one of the 22 pieces failed the test. The results are shown in Table 5.

TABLE 5

| | Block electrode | | | | | | Thin layer | | | |
|---|---|---|---|---|---|---|---|---|---|---|
| Sample | | | | L | h | | | Thickness | Via electrode | |
| No. | Material | Shape | Position | mm | mm | L/h | Material | μm | Provided/not | Position |
| 1 | — | — | Lower | — | — | — | Ni-Au | 20 | No | — |
| 2 | — | — | Upper | — | — | — | Ni-Au | 20 | Provided | Side |
| 3 | Cu | Cylinder | Upper | 1 | 0.2 | 5 | Ni-Au | 20 | Provided | Right above |
| 4 | Cu | Cylinder | Upper | 1 | 0.5 | 2 | Ni-Au | 20 | Provided | Right above |
| 5 | Cu | Cylinder | Upper | 1 | 1 | 1 | Ni-Au | 20 | Provided | Right above |
| 6 | Cu | Cylinder | Upper | 1 | 2 | 0.5 | Ni-Au | 20 | Provided | Right above |
| 7 | Cu | Cylinder | Upper | 1 | 5 | 0.2 | Ni-Au | 20 | Provided | Right above |
| 8 | Cu | Cylinder | Upper | 4 | 0.2 | 20 | Ni-Au | 20 | Provided | Right above |
| 9 | Cu | Cylinder | Upper | 0.5 | 0.5 | 1 | Ni-Au | 20 | Provided | Right above |
| 10 | Cu | Cylinder | Upper | 2 | 2 | 1 | Ni-Au | 20 | Provided | Right above |
| 13 | Cu | Rectangular prism | Upper | 1 | 0.2 | 5 | Ni-Au | 20 | Provided | Right above |
| 14 | Cu | Rectangular prism | Upper | 1 | 0.5 | 2 | Ni-Au | 20 | Provided | Right above |
| 15 | Cu | Rectangular prism | Upper | 1 | 1 | 1 | Ni-Au | 20 | Provided | Right above |
| 16 | Cu | Rectangular prism | Upper | 1 | 2 | 0.5 | Ni-Au | 20 | Provided | Right above |
| 17 | Cu | Rectangular prism | Upper | 1 | 5 | 0.2 | Ni-Au | 20 | Provided | Right above |
| 18 | Cu | Rectangular prism | Upper | 4 | 0.2 | 20 | Ni-Au | 20 | Provided | Right above |
| 19 | Cu | Rectangular prism | Upper | 0.5 | 0.5 | 1 | Ni-Au | 20 | Provided | Right above |
| 20 | Cu | Rectangular prism | Upper | 2 | 2 | 1 | Ni-Au | 20 | Provided | Right above |
| 21 | Cu | Hexagonal prism | Upper | 1 | 0.2 | 5 | Ni-Au | 20 | Provided | Right above |
| 22 | Cu | Hexagonal prism | Upper | 1 | 0.5 | 2 | Ni-Au | 20 | Provided | Right above |
| 23 | Cu | Hexagonal prism | Upper | 1 | 1 | 1 | Ni-Au | 20 | Provided | Right above |
| 24 | Cu | Hexagonal prism | Upper | 1 | 2 | 0.5 | Ni-Au | 20 | Provided | Right above |
| 25 | Cu | Hexagonal prism | Upper | 1 | 5 | 0.2 | Ni-Au | 20 | Provided | Right above |

| | Melting point | | Bonding | | Characteristics | | | |
|---|---|---|---|---|---|---|---|---|
| | Solder 1 | Solder 2 | Height difference | Wire length | Yield | | Power consumption | |
| Sample No. | ° C. | ° C. | mm | mm | % | Workability | W | Reliability |
| 1 | 280 | — | 6 | 10 | 70 | C | 3 | B |
| 2 | 280 | — | 5 | 9 | 80 | C | 2.5 | C |
| 3 | 280 | 230 | 0 | 4 | 92 | B | 1.6 | B |
| 4 | 280 | 230 | 0 | 4 | 95 | B | 1.6 | B |
| 5 | 280 | 230 | 0 | 4 | 100 | A | 1.5 | B |
| 6 | 280 | 230 | 0 | 4 | 99 | A | 1.6 | B |
| 7 | 280 | 230 | 0 | 4 | 93 | A | 1.6 | B |
| 8 | 280 | 230 | 0 | 4 | 91 | B | 1.6 | B |
| 9 | 280 | 230 | 0 | 4 | 100 | A | 1.6 | B |
| 10 | 280 | 230 | 0 | 4 | 100 | A | 1.6 | B |
| 13 | 280 | 230 | 0 | 4 | 93 | B | 1.6 | B |
| 14 | 280 | 230 | 0 | 4 | 94 | B | 1.6 | B |
| 15 | 280 | 230 | 0 | 4 | 100 | A | 1.5 | B |
| 16 | 280 | 230 | 0 | 4 | 99 | A | 1.6 | B |
| 17 | 280 | 230 | 0 | 4 | 94 | A | 1.6 | B |
| 18 | 280 | 230 | 0 | 4 | 92 | B | 1.6 | B |
| 19 | 280 | 230 | 0 | 4 | 100 | A | 1.6 | B |
| 20 | 280 | 230 | 0 | 4 | 100 | A | 1.6 | B |
| 21 | 280 | 230 | 0 | 4 | 92 | B | 1.6 | B |
| 22 | 280 | 230 | 0 | 4 | 94 | B | 1.6 | B |
| 23 | 280 | 230 | 0 | 4 | 100 | A | 1.5 | B |
| 24 | 280 | 230 | 0 | 4 | 100 | A | 1.6 | B |
| 25 | 280 | 230 | 0 | 4 | 95 | A | 1.6 | B |

| | Block electrode | | | | | | Thin layer | | | |
|---|---|---|---|---|---|---|---|---|---|---|
| Sample | | | | L | h | | | Thickness | Via electrode | |
| No. | Material | Shape | Position | mm | mm | L/h | Material | μm | Provided/not | Position |
| 26 | Cu | Octagonal prism | Upper | 4 | 0.5 | 8 | Ni-Au | 20 | Provided | Right above |
| 27 | Cu | Octagonal prism | Upper | 0.5 | 1 | 0.5 | Ni-Au | 20 | Provided | Right above |
| 28 | Cu | Octagonal prism | Upper | 2 | 2 | 1 | Ni-Au | 20 | Provided | Right above |
| 29 | Cu | Rectangular prism | Upper | 1 | 1 | 1 | Ni-Au | 20 | Provided | Side |
| 30 | Cu | Rectangular prism | Upper | 1 | 1 | 1 | Ni-Au | 20 | No | Right above |
| 31 | Al | Rectangular prism | Upper | 1 | 1 | 1 | Ni-Au | 20 | Provided | Right above |
| 32 | Ag | Rectangular prism | Upper | 1 | 1 | 1 | Ni-Au | 20 | Provided | Right above |
| 33 | W | Rectangular prism | Upper | 1 | 1 | 1 | Ni-Au | 20 | Provided | Right above |
| 34 | Ti | Rectangular prism | Upper | 1 | 1 | 1 | Ni-Au | 20 | Provided | Right above |
| 35 | Fe | Rectangular prism | Upper | 1 | 1 | 1 | Ni-Au | 20 | Provided | Right above |
| 36 | Zn | Rectangular prism | Upper | 1 | 1 | 1 | Ni-Au | 20 | Provided | Right above |
| 37 | Ni | Rectangular prism | Upper | 1 | 1 | 1 | Ni-Au | 20 | Provided | Right above |
| 38 | Mg | Rectangular prism | Upper | 1 | 1 | 1 | Ni-Au | 20 | provided | Right above |
| 39 | Cu | Rectangular prism | Upper | 1 | 1 | 1 | Sn | 20 | Provided | Right above |
| 40 | Cu | Rectangular prism | Upper | 1 | 1 | 1 | Pt | 20 | Provided | Right above |
| 41 | Cu | Rectangular prism | Upper | 1 | 1 | 1 | Co | 20 | Provided | Right above |
| 42 | Cu | Rectangular prism | Upper | 1 | 1 | 1 | Ni-Au | 20 | Provided | Right above |
| 43 | Cu | Rectangular prism | Upper | 1 | 1 | 1 | Ni-Au | 20 | Provided | Right above |
| 44 | Cu | Rectangular prism | Upper | 1 | 1 | 1 | Ni-Au | 20 | Provided | Right above |
| 45 | Cu | Rectangular prism | Upper | 1 | 1 | 1 | Ni-Au | 20 | Provided | Right above |
| 46 | Cu | Rectangular prism | Upper | 1 | 1 | 1 | Ni-Au | 20 | Provided | Right above |
| 47 | Cu | Rectangular prism | Upper | 1 | 1 | 1 | Ni-Au | 20 | Provided | Right above |
| 48 | Cu | Rectangular prism | Upper | 1 | 1 | 1 | Ni-Au | 20 | Provided | Right above |
| 49 | Cu | Rectangular prism | Upper | 1 | 1 | 1 | Ni-Au | 20 | Provided | Right above |
| 50 | Cu | Rectangular prism | Upper | 1 | 1 | 1 | Ni-Au | 20 | Provided | Right above |
| 51 | Cu | Rectangular prism | Upper | 1 | 1 | 1 | Ni-Au | 20 | Provided | Right above |

| | Melting point | | Bonding | | Characteristics | | | |
|---|---|---|---|---|---|---|---|---|
| | Solder 1 | Solder 2 | Height difference | Wire length | Yield | | Power consumption | |
| Sample No. | ° C. | ° C. | mm | mm | % | Workability | W | Reliability |
| 26 | 280 | 230 | 0 | 4 | 94 | B | 1.6 | B |
| 27 | 280 | 230 | 0 | 4 | 100 | A | 1.6 | B |
| 28 | 280 | 230 | 0 | 4 | 100 | A | 1.6 | B |
| 29 | 280 | 230 | 0 | 4 | 91 | A | 1.6 | B |
| 30 | 280 | 230 | 0 | 4 | 100 | A | 1.6 | B |
| 31 | 280 | 230 | 0 | 4 | 100 | A | 1.6 | B |
| 32 | 280 | 230 | 0 | 4 | 100 | A | 1.6 | B |
| 33 | 280 | 230 | 0 | 4 | 100 | A | 1.6 | B |
| 34 | 280 | 230 | 0 | 4 | 100 | A | 1.6 | B |
| 35 | 280 | 230 | 0 | 4 | 100 | A | 1.6 | B |
| 36 | 280 | 230 | 0 | 4 | 100 | A | 1.6 | B |
| 37 | 280 | 230 | 0 | 4 | 100 | A | 1.6 | B |
| 38 | 280 | 230 | 0 | 4 | 100 | A | 1.6 | B |
| 39 | 280 | 230 | 0 | 4 | 100 | A | 1.6 | B |
| 40 | 280 | 230 | 0 | 4 | 100 | A | 1.6 | B |
| 41 | 280 | 230 | 0 | 4 | 100 | A | 1.6 | B |
| 42 | 280 | 180 | 0 | 4 | 100 | A | 1.6 | B |
| 43 | 230 | 180 | 0 | 4 | 100 | A | 1.6 | B |
| 44 | 230 | 280 | 0 | 4 | 100 | A | 1.6 | B |
| 45 | 180 | 280 | 0 | 4 | 100 | A | 1.6 | B |
| 46 | 180 | 230 | 0 | 4 | 100 | A | 1.6 | B |
| 47 | 280 | 280 | 0 | 4 | 100 | A | 1.6 | B |
| 48 | 230 | 230 | 0 | 4 | 100 | A | 1.6 | B |
| 49 | 180 | 180 | 0 | 4 | 100 | A | 1.6 | B |
| 50 | 280 | 230 | 1 | 5 | 97 | B | 1.8 | B |
| 51 | 280 | 230 | 3 | 7 | 95 | B | 2.0 | B |

*Sample beyond the scope of the present invention.
Lower: Lower substrate planar electrode
Upper: Upper substrate planar electrode
Right above: Right above the thermoelectric element.
Side: Not right above the thermoelectric element.
[Workability]
B: 11 to 19 seconds per line
A: 10 seconds per line or less
C: 20 seconds per line or more
[Energization cycle test]
B: ΔR is 5% or less.
C: ΔR exceeds 5%.

Samples Nos. 3 through 51 having the structure shown in FIGS. 7A and 7B showed satisfactory performance in both workability and reliability test, with yield of 90% or higher and power consumption of 2 W or less. Among these, Among these, samples Nos. 5, 6, 9, 10, 15, 16, 19, 20, 23, 24, 27, 38 and 30 through 49 showed satisfactory performance in both workability and reliability test, with yield of 99% or higher and power consumption of 1.6 W or less, and were excellent in all evaluations.

Sample No. 1 where the lead wire was joined with the planar electrode of the lower support substrate, in contrast, showed low yield of 70% and high power consumption of 3 W, and workability was inferior to the samples of the present invention. Sample No. 2 where the planar electrode was formed on the upper support substrate showed low yield of 80% and high power consumption of 2.5 W, and workability and reliability were inferior to the samples of the present invention.

1. A thermoelectric module comprising:
a support substrate,
the same number of N-type and P-type thermoelectric elements disposed on said support substrate,
wiring conductor that electrically connects said plurality of thermoelectric elements in series and
an external connection terminal electrically connected to said wiring conductor,
wherein said N-type thermoelectric elements and said P-type thermoelectric elements have different values of resistivity.

2. The thermoelectric module according to claim 1, wherein said N-type thermoelectric elements comprises a melt-formed material and said P-type thermoelectric elements comprises a sintered material.

3. The thermoelectric module according to claim 1, wherein values of power factor ((Seebeck coefficient)²/resistivity) of said P-type thermoelectric elements is not less than 4×10⁻³ W/mK².

4. The thermoelectric module according to claim 1, wherein the ratio of resistivity of the N-type thermoelectric element to that of the P-type thermoelectric element (N-type/P-type) is in a range from 0.7 to 0.95.

5. The thermoelectric module according to claim 1, wherein the ratio of resistivity of the N-type thermoelectric element to that of the P-type thermoelectric element (N-type/P-type) is in a range from 1.05 to 1.30.

6. The thermoelectric module according to claim 1, wherein said N-type element comprises rod-shaped crystal fabricated by unidirectional solidification.

7. The thermoelectric module according to claim 1, wherein said P-type element comprises a sintered material having particle size of 50 μm or less.

8. A thermoelectric module comprising:
a support substrate,
a plurality of thermoelectric elements disposed on said support substrate,
wiring conductor that electrically connects said plurality of thermoelectric elements in series and
an external connection terminal electrically connected to said wiring conductor,
wherein cross section of said wiring conductor is either rectangular or a trapezoid with the upper side located on the element bonding surface side is longer than the lower side located on the support substrate surface side.

9. The thermoelectric module according to claim 8, wherein the angle between the element bonding surface and the side face of said wiring conductor is in a range from 45 to 90°.

10. The thermoelectric module according to claim 8, wherein parallelism between the upper side and the lower side of the wiring conductor on the element bonding surface is within 0.1 mm.

11. The thermoelectric module of claim 8 wherein flatness of the wiring conductor on the element bonding surface is within 0.1 mm.

12. A thermoelectric module comprising
a support substrate,
a plurality of thermoelectric elements disposed on said support substrate,
wiring conductor that electrically connects said of thermoelectric elements in series,
an external connection terminal electrically connected to said wiring conductor and
lead member electrically connected to said external connection terminal,
wherein Sn content in a solder that bonds said lead member to said external connection terminal is in a range from 12% to 40% by weight.

13. The thermoelectric module according to claim 12, wherein void ratio of said thermoelectric elements is within 10%.

14. The thermoelectric module according to claim 12, wherein a diffusion layer of said lead member component having thickness of 0.1 μm or more is formed in said solder, and said diffusion layer exists in 20% or more of the bonded area of said lead member.

15. The thermoelectric module according to claim 14, wherein interface of the diffusion layer of said lead member component and a non-diffusion layer is formed in wavy shape in at least one of sections that intersect said support substrate at right angles.

16. The thermoelectric module according to claim 14, wherein the diffusion layer of said lead member component is denser than the surrounding non-diffusion layer.

17. The thermoelectric module according to claim 12, wherein said support substrate includes an upper support substrate and a lower support substrate that oppose each other so as to interpose said thermoelectric elements, said external connection terminal is planar and is formed on a surface opposite to the surface of said upper support substrate whereon the thermoelectric element is bonded, and said lead member has a block shape and is provided integrally with said external connection terminal.

18. The thermoelectric module according to claim 17, wherein said upper support substrate has a via electrode so that said external connection terminal and said wiring conductor are electrically connected with each other via said via electrode.

19. The thermoelectric module according to claim 17, wherein said via electrode is provided right above said thermoelectric element.

20. The thermoelectric module according to claim 17, wherein ratio of maximum length to height of said lead member is in a range from 0.2 to 20.

21. A package for thermoelectric module comprising a container, connection electrode provided in said container and the thermoelectric module according to claim 17, wherein top surface of the block-shaped lead member and said connection electrode are located at substantially the same height.
